(19) United States
(12) Patent Application Publication
(10) Pub. No.: US 2026/0223467 A1
(43) Pub. Date: Jul. 30, 2026

(54) SEMICONDUCTOR APPARATUS

(71) Applicant: SONY SEMICONDUCTOR SOLUTIONS CORPORATION, Kanagawa (JP)

(72) Inventors: Tadashi IIJIMA, Kanagawa (JP); Isaya KITAMURA, Kanagawa (JP)

(73) Assignee: SONY SEMICONDUCTOR SOLUTIONS CORPORATION, Kanagawa (JP)

(21) Appl. No.: 19/146,107

(22) PCT Filed: Jan. 9, 2024
(86) PCT No.: PCT/JP2024/000098

§ 371 Date: Jul. 7, 2025

(30) Foreign Application Priority Data
Jan. 17, 2023 (JP) 2023-005087

(51) Int. Cl. H10F 39/00; H10F 39/18

(52) U.S. Cl. CPC H10F 39/80373; H10F 39/014; H10F 39/182; H10F 39/80377

(57) ABSTRACT

A semiconductor apparatus that includes a charge transfer section, a separation section, and a notch portion. The charge transfer section is configured by a MOS transistor including a first semiconductor region disposed in a semiconductor substrate, a second semiconductor region disposed in the vicinity of a surface of the semiconductor substrate, and a transfer gate disposed in a recess formed in the surface of the semiconductor substrate and having a bottom portion being a gate electrode formed in the vicinity of the first semiconductor region, and is configured to transfer a charge from one of the first semiconductor region and the second semiconductor region to the other. The separation section is embedded in the surface of the semiconductor substrate and is disposed adjacent to a side surface of the transfer gate. The notch portion is formed on the side surface of the transfer gate adjacent to the separation section.

### FIELD

The present disclosure relates to a semiconductor apparatus.

### BACKGROUND

A photodetection apparatus, which is a semiconductor apparatus that images a subject and generates an image signal, includes a pixel array section in which pixels that generate an image signal on the basis of incident light are arranged in a two-dimensional matrix. In this pixel, a photoelectric conversion section such as a photodiode that performs photoelectric conversion of incident light, a charge holding section that holds a charge generated by photoelectric conversion, and a charge transfer section that transfers the charge of the photoelectric conversion section to the charge holding section are arranged. Furthermore, in the pixel, a pixel circuit that generates an image signal on the basis of the charge held in the charge holding section is arranged.

In this pixel, the charge generated by the photoelectric conversion section during the exposure period is transferred to the charge holding section and held therein. After the end of the exposure period, the pixel circuit generates an image signal on the basis of the charge held in the charge holding section, and outputs the image signal to the peripheral circuit of the pixel array section.

For such a photodetection apparatus, a back-illuminated photodetection apparatus is used in which a charge holding section and a pixel circuit are formed on a front surface side of a semiconductor substrate, a photoelectric conversion section is formed inside the semiconductor substrate, and light from a subject enters the photoelectric conversion section from a back surface side of the semiconductor substrate. In this photodetection apparatus, a charge transfer section that transfers the charge of the photoelectric conversion section inside the semiconductor substrate to the front surface side of the semiconductor substrate is disposed. The charge transfer section is configured by a MOS transistor embedded in a semiconductor substrate and having a vertical gate configured in a columnar shape to transfer a charge in a thickness direction of the semiconductor substrate.

For such a back-illuminated photodetection apparatus, a photodetection apparatus (solid-state imaging apparatus) has been proposed in which a semiconductor layer grown on an inner wall of a hole portion formed in a semiconductor substrate is used as a channel region that is a region where a channel of a charge transfer section is formed (see, for example, Patent Literature 1). In this photodetection apparatus, a vertical gate is formed in a hole portion after the channel region is generated.

### CITATION LIST

### Patent Literature

Patent Literature 1: JP 2011-014751 A

### SUMMARY

### Technical Problem

However, in the above-described conventional technique, there is a problem that miniaturization of pixels is difficult. When the pixel area is reduced, it is necessary to separate elements by arranging a separation section such as shallow trench isolation (STI) on the surface of the semiconductor substrate. In the above-described conventional technique, it is necessary to form the charge transfer section while avoiding the separation section, and it becomes difficult to miniaturize the pixels.

Therefore, the present disclosure proposes a photodetection apparatus having miniaturized pixels.

### Solution to Problem

A semiconductor apparatus according to the present disclosure includes a charge transfer section, a separation section and a notch portion. The charge transfer section is configured by a MOS transistor including a first semiconductor region disposed in a semiconductor substrate, a second semiconductor region disposed in the vicinity of a surface of the semiconductor substrate, and a transfer gate disposed in a recess formed in the surface of the semiconductor substrate and having a bottom portion being a gate electrode formed in the vicinity of the first semiconductor region, and is configured to transfer a charge from one of the first semiconductor region and the second semiconductor region to the other. The separation section is embedded in the surface of the semiconductor substrate and is disposed adjacent to a side surface of the transfer gate. The notch portion is formed on the side surface of the transfer gate adjacent to the separation section.

### BRIEF DESCRIPTION OF DRAWINGS

FIG. 1 is a diagram illustrating an example of a schematic configuration of a photodetection apparatus according to a first embodiment of the present disclosure.

FIG. 2 is a diagram illustrating another example of a schematic configuration of the photodetection apparatus according to the first embodiment of the present disclosure.

FIG. 3 is a diagram illustrating a configuration example of a pixel according to an embodiment of the present disclosure.

FIG. 4 is a diagram illustrating a configuration example of a pixel according to an embodiment of the present disclosure.

FIG. 5 is a diagram illustrating a configuration example of a pixel according to the first embodiment of the present disclosure.

FIG. 6 is a diagram illustrating a configuration example of a charge transfer section according to the first embodiment of the present disclosure.

FIG. 7A is a diagram illustrating an example of a method for manufacturing the photodetection apparatus according to the first embodiment of the present disclosure.

FIG. 7B is a diagram illustrating an example of the method for manufacturing the photodetection apparatus according to the first embodiment of the present disclosure.

FIG. 7C is a diagram illustrating an example of the method for manufacturing the photodetection apparatus according to the first embodiment of the present disclosure.

FIG. 7D is a diagram illustrating an example of the method for manufacturing the photodetection apparatus according to the first embodiment of the present disclosure.

FIG. 7E is a diagram illustrating an example of the method for manufacturing the photodetection apparatus according to the first embodiment of the present disclosure.

FIG. 7F is a diagram illustrating an example of the method for manufacturing the photodetection apparatus according to the first embodiment of the present disclosure.

FIG. 7G is a diagram illustrating an example of the method for manufacturing the photodetection apparatus according to the first embodiment of the present disclosure.

FIG. 8 is a diagram illustrating a configuration example of a charge transfer section according to a second embodiment of the present disclosure.

FIG. 9A is a diagram illustrating an example of a method for manufacturing the photodetection apparatus according to the second embodiment of the present disclosure.

FIG. 9B is a diagram illustrating an example of the method for manufacturing the photodetection apparatus according to the second embodiment of the present disclosure.

FIG. 9C is a diagram illustrating an example of the method for manufacturing the photodetection apparatus according to the second embodiment of the present disclosure.

FIG. 10 is a diagram illustrating a configuration example of a charge transfer section according to a third embodiment of the present disclosure.

FIG. 11A is a diagram illustrating an example of a method for manufacturing the photodetection apparatus according to the third embodiment of the present disclosure.

FIG. 11B is a diagram illustrating an example of the method for manufacturing the photodetection apparatus according to the third embodiment of the present disclosure.

FIG. 11C is a diagram illustrating an example of the method for manufacturing the photodetection apparatus according to the third embodiment of the present disclosure.

FIG. 11D is a diagram illustrating an example of the method for manufacturing the photodetection apparatus according to the third embodiment of the present disclosure.

FIG. 11E is a diagram illustrating an example of the method for manufacturing the photodetection apparatus according to the third embodiment of the present disclosure.

FIG. 12 is a diagram illustrating a configuration example of a charge transfer section according to a fourth embodiment of the present disclosure.

FIG. 13A is a diagram illustrating an example of a method for manufacturing the photodetection apparatus according to the fourth embodiment of the present disclosure.

FIG. 13B is a diagram illustrating an example of the method for manufacturing the photodetection apparatus according to the fourth embodiment of the present disclosure.

FIG. 13C is a diagram illustrating an example of the method for manufacturing the photodetection apparatus according to the fourth embodiment of the present disclosure.

FIG. 14 is a diagram illustrating a configuration example of a charge transfer section according to a fifth embodiment of the present disclosure.

FIG. 15A is a diagram illustrating an example of a method for manufacturing the photodetection apparatus according to the fifth embodiment of the present disclosure.

FIG. 15B is a diagram illustrating an example of the method for manufacturing the photodetection apparatus according to the fifth embodiment of the present disclosure.

FIG. 15C is a diagram illustrating an example of the method for manufacturing the photodetection apparatus according to the fifth embodiment of the present disclosure.

FIG. 15D is a diagram illustrating an example of the method for manufacturing the photodetection apparatus according to the fifth embodiment of the present disclosure.

FIG. 15E is a diagram illustrating an example of the method for manufacturing the photodetection apparatus according to the fifth embodiment of the present disclosure.

FIG. 15F is a diagram illustrating an example of the method for manufacturing the photodetection apparatus according to the fifth embodiment of the present disclosure.

FIG. 15G is a diagram illustrating an example of the method for manufacturing the photodetection apparatus according to the fifth embodiment of the present disclosure.

FIG. 15H is a diagram illustrating an example of the method for manufacturing the photodetection apparatus according to the fifth embodiment of the present disclosure.

FIG. 16 is a diagram illustrating a configuration example of a charge transfer section according to a sixth embodiment of the present disclosure.

FIG. 17 is a diagram illustrating an example of a method for manufacturing the photodetection apparatus according to the sixth embodiment of the present disclosure.

FIG. 18 is a diagram illustrating a configuration example of a charge transfer section according to a seventh embodiment of the present disclosure.

FIG. 19A is a diagram illustrating an example of a method for manufacturing the photodetection apparatus according to the seventh embodiment of the present disclosure.

FIG. 19B is a diagram illustrating an example of the method for manufacturing the photodetection apparatus according to the seventh embodiment of the present disclosure.

FIG. 19C is a diagram illustrating an example of the method for manufacturing the photodetection apparatus according to the seventh embodiment of the present disclosure.

FIG. 19D is a diagram illustrating an example of the method for manufacturing the photodetection apparatus according to the seventh embodiment of the present disclosure.

FIG. 19E is a diagram illustrating an example of the method for manufacturing the photodetection apparatus according to the seventh embodiment of the present disclosure.

FIG. 20 is a diagram illustrating a configuration example of a charge transfer section according to an eighth embodiment of the present disclosure.

FIG. 21 is a diagram illustrating an example of a method for manufacturing the photodetection apparatus according to the eighth embodiment of the present disclosure.

FIG. 22 is a block diagram illustrating a configuration example of an imaging apparatus mounted on an electronic device.

FIG. 23 is a block diagram depicting an example of schematic configuration of a vehicle control system as an example of a mobile body control system to which the technology according to an embodiment of the present disclosure can be applied.

FIG. 24 is a diagram depicting an example of an installation position of an imaging section.

FIG. 25 is a view depicting an example of a schematic configuration of an endoscopic surgery system to which the technology according to an embodiment of the present disclosure (the present technology) can be applied.

FIG. 26 is a block diagram depicting an example of functional configurations of a camera head and a CCU depicted in FIG. 25.

### DESCRIPTION OF EMBODIMENTS

Hereinafter, embodiments of the present disclosure will be described in detail with reference to the drawings. The description will be given in the following order. Note that, in each of the following embodiments, the same parts are denoted by the same reference signs, and redundant description will be omitted.
1. First Embodiment
2. Second Embodiment
3. Third Embodiment
4. Fourth Embodiment
5. Fifth Embodiment
6. Sixth Embodiment
7. Seventh Embodiment
8. Eighth Embodiment
9. Configuration of Electronic Device
10. Application Example to Mobile Body
11. Application Example to Endoscopic Surgery System

### 1. First Embodiment

### [Configuration of Photodetection Apparatus]

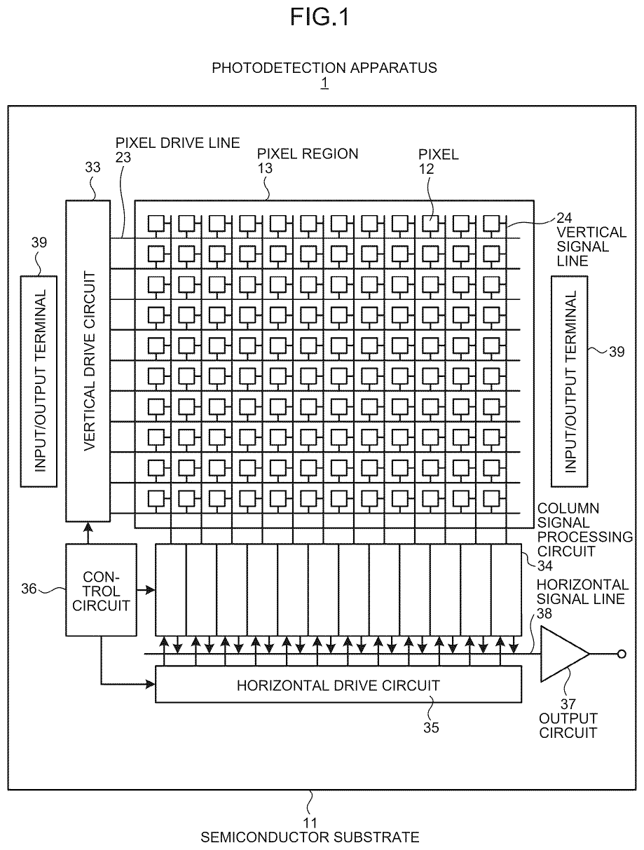

FIG. 1 is a diagram illustrating an example of a schematic configuration of a photodetection apparatus according to a first embodiment of the present disclosure. As illustrated in FIG. 1, a photodetection apparatus 1 of the present example includes a pixel array section (so-called imaging region) 13 in which pixels 12 including a plurality of photoelectric conversion sections are regularly and two-dimensionally arranged on a semiconductor substrate 11, for example, a silicon substrate, and a peripheral circuit section. The pixel 12 includes, for example, a photodiode serving as a photoelectric conversion section and a plurality of pixel transistors (so-called MOS transistors). The plurality of pixel transistors can include, for example, three transistors of a transfer transistor, a reset transistor, and an amplification transistor. In addition, a selection transistor may be added to form four transistors. The pixels 12 may have a shared pixel structure. This pixel sharing structure includes a plurality of photodiodes, a plurality of transfer transistors, one shared floating diffusion region, and one shared pixel transistor. Note that the photodetection apparatus 1 is an example of a “semiconductor apparatus” of the present disclosure.

The peripheral circuit section includes a vertical drive circuit 33, a column signal processing circuit 34, a horizontal drive circuit 35, an output circuit 37, a control circuit 36, and the like.

The control circuit 36 receives an input clock and data instructing an operation mode and the like, and outputs data such as internal information of the imaging element. That is, the control circuit 36 generates a clock signal or a control signal serving as a reference of operations of the vertical drive circuit 33, the column signal processing circuit 34, the horizontal drive circuit 35, and the like on the basis of the vertical synchronization signal, the horizontal synchronization signal, and the master clock. Then, these signals are input to the vertical drive circuit 33, the column signal processing circuit 34, the horizontal drive circuit 35, and the like.

The vertical drive circuit 33 includes, for example, a shift register, selects a pixel drive line 23, supplies a pulse for driving pixels to the selected pixel drive line, and drives the pixels in units of rows. That is, the vertical drive circuit 33 sequentially selects and scans each pixel 12 in the pixel region 13 in the vertical direction in units of rows, and supplies a pixel signal based on a signal charge generated according to the amount of received light in, for example, a photodiode serving as a photoelectric conversion section of each pixel 12 to the column signal processing circuit 34 through the vertical signal line 24.

The column signal processing circuit 34 is arranged, for example, for each column of the pixels 12, and performs signal processing such as noise removal on the signals output from the pixels 12 of one row for each pixel column. That is, the column signal processing circuit 34 performs signal processing such as correlated double sampling (CDS) for removing fixed pattern noise unique to the pixel 12, signal amplification, and AD conversion. A horizontal selection switch (not illustrated) is connected and provided between an output stage of the column signal processing circuit 34 and a horizontal signal line 38.

The horizontal drive circuit 35 includes, for example, a shift register, sequentially selects each of the column signal processing circuits 34 by sequentially outputting horizontal scanning pulses, and causes each of the column signal processing circuits 34 to output a pixel signal to the horizontal signal line 38.

The output circuit 37 performs signal processing on the signals sequentially supplied from each of the column signal processing circuits 34 through the horizontal signal line 38, and outputs the processed signals. For example, only buffering may be performed, or black level adjustment, column variation correction, various digital signal processing, and the like may be performed. An input/output terminal 39 exchanges signals with the outside.

Note that the drawing illustrates an example of a case where the photodetection apparatus 1 is formed on the semiconductor substrate 11. The photodetection apparatus 1 can also include a plurality of semiconductor substrates. By laminating a plurality of substrates constituting the photodetection apparatus 1, the size (area) of the photodetection apparatus 1 can be reduced. An example of this case will be described next.

### [Another Configuration of Photodetection Apparatus]

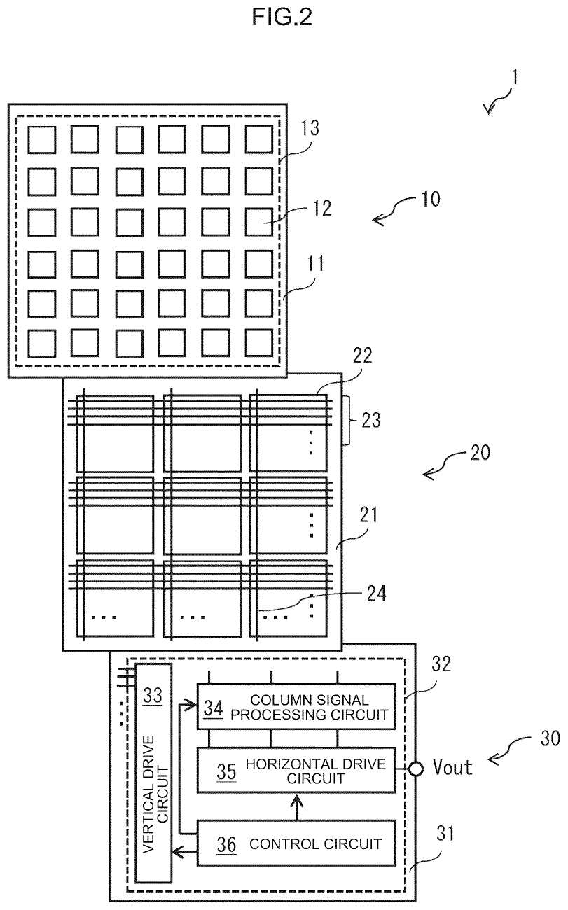

FIG. 2 is a diagram illustrating another example of the schematic configuration of the photodetection apparatus according to the first embodiment of the present disclosure. The photodetection apparatus 1 in the drawing includes three substrates (first substrate 10, second substrate 20, and third substrate 30). The photodetection apparatus 1 has a three-dimensional structure formed by bonding three substrates (first substrate 10, second substrate 20, and third substrate 30). The first substrate 10, the second substrate 20, and the third substrate 30 are laminated in this order.

The first substrate 10 includes a plurality of pixels 12 that performs photoelectric conversion on the semiconductor substrate 11. The plurality of pixels 12 is provided in a matrix in the pixel array section 13 of the first substrate 10. The second substrate 20 includes, on a semiconductor substrate 21, one pixel circuit 22 for each of four pixels 12 that outputs a pixel signal based on the charge output from the pixel 12. The second substrate 20 includes a plurality of pixel drive lines 23 extending in the row direction and a plurality of vertical signal lines 24 extending in the column direction. The third substrate 30 includes a logic circuit 32 that processes a pixel signal on a semiconductor substrate 31. The logic circuit 32 includes, for example, a vertical drive circuit 33, a column signal processing circuit 34, a horizontal drive circuit 35, and a control circuit 36. The logic circuit 32 (specifically, the horizontal drive circuit 35) outputs the output voltage Vout for each pixel 12 to the outside. In the logic circuit 32, for example, a low-resistance region constituted by silicide formed using a salicide (self aligned silicide) process such as CoSi₂ or NiSi may be formed on the surface of the impurity diffusion region in contact with the source electrode and the drain electrode.

For example, the vertical drive circuit 33 sequentially selects the plurality of pixels 12 row by row. The column signal processing circuit 34 performs, for example, correlated double sampling (CDS) processing on the pixel signal output from each pixel 12 of the row selected by the vertical drive circuit 33. The column signal processing circuit 34 extracts a signal level of a pixel signal by performing CDS processing, for example, and holds pixel data corresponding to the amount of received light of each pixel 12. For example, the horizontal drive circuit 35 sequentially outputs the pixel data held in the column signal processing circuit 34 to the outside. The control circuit 36 controls driving of each block (vertical drive circuit 33, column signal processing circuit 34, and horizontal drive circuit 35) in the logic circuit 32, for example.

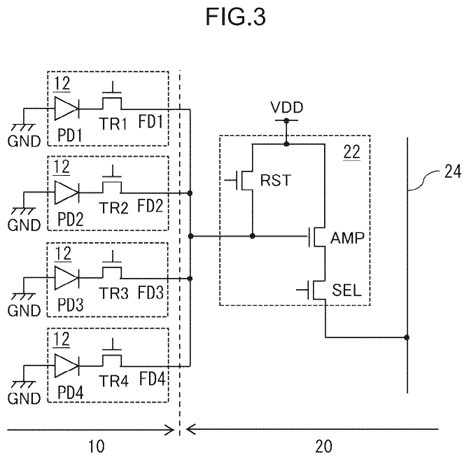

FIG. 3 is a diagram illustrating a configuration example of a pixel according to an embodiment of the present disclosure. FIG. 3 is a circuit diagram illustrating a configuration example of the pixel 12, and illustrates an example of the pixel 12 and the readout circuit 22. Hereinafter, as illustrated in FIG. 3, a case where four pixels 12 share one readout circuit 22 will be described. Here, “sharing” means that the outputs of the four pixels 12 are input to the common readout circuit 22. The column signal processing circuit 34 corresponds to a specific example of a “processing circuit” of the present disclosure.

Each pixel 12 has a common component. In FIG. 3, in order to distinguish the components of each pixel 12 from each other, an identification number (1, 2, 3, and 4) is added to the end of the reference sign of the component of each pixel 12. Hereinafter, in a case where it is necessary to distinguish the components of each pixel 12 from each other, an identification number is assigned to the end of the reference sign of the component of each pixel 12, but in a case where it is not necessary to distinguish the components of each pixel 12 from each other, the identification number at the end of the reference sign of the component of each pixel 12 is omitted. Note that the photodetection apparatus 1 is a specific example of a “semiconductor apparatus” of the present disclosure.

Each pixel 12 includes, for example, a photodiode PD, a charge transfer section TR electrically connected to the photodiode PD, and a floating diffusion FD constituting a charge holding section that temporarily holds a charge output from the photodiode PD via the charge transfer section TR. The photodiode PD corresponds to a specific example of a “photoelectric conversion element” of the present disclosure. The photodiode PD performs photoelectric conversion to generate a charge corresponding to the amount of received light. The cathode of the photodiode PD is electrically connected to the source of the charge transfer section TR, and the anode of the photodiode PD is electrically connected to a reference potential line (for example, ground). The drain of the charge transfer section TR is electrically connected to the floating diffusion FD, and the gate of the charge transfer section TR is electrically connected to the pixel drive line 23. The charge transfer section TR is, for example, a metal oxide semiconductor (MOS) transistor.

The floating diffusion FD of each pixel 12 sharing one readout circuit 22 is electrically connected to each other and is electrically connected to an input terminal of the common readout circuit 22. The readout circuit 22 includes, for example, a reset transistor RST, a selection transistor SEL, and an amplification transistor AMP. Note that the selection transistor SEL may be omitted as necessary. The source of the reset transistor RST (the input terminal of the readout circuit 22) is electrically connected to the floating diffusion FD, and the drain of the reset transistor RST is electrically connected to the power supply line VDD and the drain of the amplification transistor AMP. The gate of the reset transistor RST is electrically connected to the pixel drive line 23 (see FIG. 2). The source of the amplification transistor AMP is electrically connected to the drain of the selection transistor SEL, and the gate of the amplification transistor AMP is electrically connected to the source of the reset transistor RST. The source of the selection transistor SEL (the output terminal of the readout circuit 22) is electrically connected to the vertical signal line 24, and the gate of the selection transistor SEL is electrically connected to the pixel drive line 23 (see FIG. 2).

When turned on, the charge transfer section TR transfers the charge of the photodiode PD to the floating diffusion region FD. The reset transistor RST resets the potential of the floating diffusion region FD to a predetermined potential. When the reset transistor RST is turned on, the potential of the floating diffusion region FD is reset to the potential of the power supply line VDD. The selection transistor SEL controls an output timing of the pixel signal from the pixel circuit 22. The amplification transistor AMP generates a signal of a voltage corresponding to the level of the charge held in the floating diffusion region FD as a pixel signal. The amplification transistor AMP constitutes a source follower type amplifier, and outputs a pixel signal having a voltage corresponding to the level of the charge generated in the photodiode PD. When the selection transistor SEL is turned on, the amplification transistor AMP outputs a voltage corresponding to the potential of the floating diffusion region FD to the column signal processing circuit 34 via the vertical signal line 24. The reset transistor RST, the amplification transistor AMP, and the selection transistor SEL are, for example, MOS transistors. Note that the pixel circuit 22 is an example of a “signal generation section” of the present disclosure.

### [Configuration of Pixel]

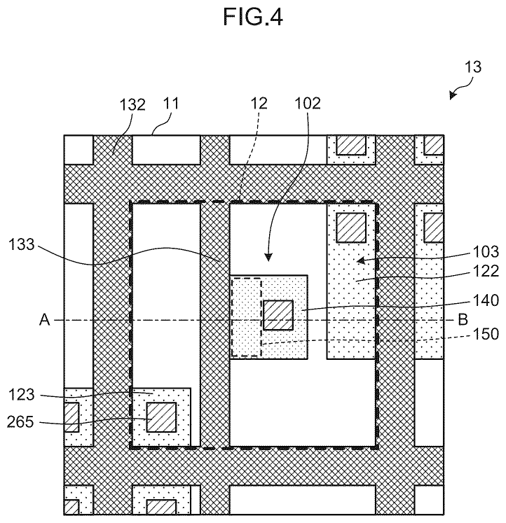

FIG. 4 is a diagram illustrating a configuration example of a pixel according to an embodiment of the present disclosure. The drawing is a diagram illustrating a configuration example of the pixel 12 arranged in the pixel array section 13. Furthermore, the drawing is a diagram illustrating a configuration of the pixel 12 on the front surface side of the semiconductor substrate 11. A dotted rectangle in the drawing represents a region of the pixel 12. In the pixel 12, a photoelectric conversion section 101 (not illustrated), a charge transfer section 102 (corresponding to TR in FIG. 3), and a charge holding section 103 (corresponding to FD in FIG. 2) are arranged.

A separation section 132 is arranged at the boundary of the pixel 12. Furthermore, a separation section 133 is also arranged inside the pixel 12. The separation section 133 separates elements arranged in the pixel 12.

The charge holding section 103 is arranged at an upper corner portion of the pixel 12 in the drawing. The charge holding section 103 includes a semiconductor region 122 constituting a floating diffusion region. Furthermore, the charge transfer section 102 is arranged in a central portion of the pixel 12.

A semiconductor region 123 is arranged at a lower corner portion of the pixel 12 in the drawing. The semiconductor region 123 is a region that transmits the reference potential to the well region of the semiconductor substrate 11 of the pixel 12.

A through wiring 265 is arranged in the semiconductor regions 122 and 123 and a transfer gate 140. The through wiring 265 is connected to a wiring 262 of the semiconductor substrate 21 described later. Note that the through wiring 265 connected to the above-described semiconductor region 123 is referred to as a well contact.

As described later, the photoelectric conversion section 101 is formed inside the semiconductor substrate 11. The charge transfer section 102 includes a MOS transistor that transfers a charge in the thickness direction of the semiconductor substrate 11. The MOS transistor includes a gate electrode arranged to be embedded in the surface of the semiconductor substrate 11 and having a bottom portion formed in the vicinity of the photoelectric conversion section 101. This gate electrode is referred to as a transfer gate. In the drawing, the transfer gate 140 is illustrated. The transfer gate 140 is an electrode configured in a columnar shape and corresponds to the above-described vertical gate. The transfer gate 140 in the drawing is disposed adjacent to the separation section 133. In addition, a notch portion 150 is formed at the bottom portion of the transfer gate 140. A broken-line rectangle in the drawing represents a region of the notch portion 150.

Note that the configuration of the pixel 12 is not limited to this example. For example, elements such as the reset transistor RST, the selection transistor SEL, and the amplification transistor AMP can be disposed on the semiconductor substrate 11. In this case, the separation section 133 is disposed between these elements and the charge transfer section 102.

### [Configuration of Cross Section of Pixel]

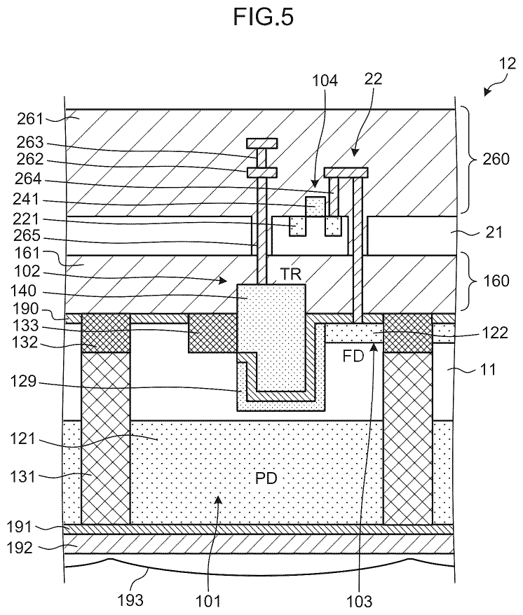

FIG. 5 is a diagram illustrating a configuration example of a pixel according to the first embodiment of the present disclosure. The drawing is a cross-sectional view illustrating a configuration example of the pixel 12. The pixel 12 in the drawing includes a semiconductor substrate 11, separation sections 131 and 132, insulating films 190 and 191, a wiring region 160, a semiconductor substrate 21, a wiring region 260, a color filter 192, and an on-chip lens 193. Note that the drawing is a view schematically illustrating a shape of a cross section taken along line A-B in FIG. 4.

The semiconductor substrate 11 is a semiconductor substrate on which the photoelectric conversion section 101 is disposed. The charge transfer section 102 and the charge holding section 103 are further disposed on the semiconductor substrate 11 in the drawing. The semiconductor substrate 11 can be constituted by, for example, silicon (Si). The photoelectric conversion section 101 is disposed in a well region formed in the semiconductor substrate 11. For convenience, the semiconductor substrate 11 in the drawing is assumed to constitute a p-type well region. By arranging n-type and p-type semiconductor regions in the p-type well region, an element (diffusion layer thereof) can be formed.

A rectangle described in the semiconductor substrate 11 in the drawing represents an n-type semiconductor region. The photoelectric conversion section 101 includes an n-type semiconductor region 121. Specifically, a photodiode constituted by a pn junction formed at an interface between the n-type semiconductor region 121 and a surrounding p-type well region corresponds to the photoelectric conversion section 101.

The charge holding section 103 includes an n-type semiconductor region 122 configured to have a relatively high impurity concentration. The n-type semiconductor region 122 constitutes the above-described floating diffusion region.

The charge transfer section 102 includes the semiconductor regions 121 and 122 and the transfer gate 140. The n-type semiconductor regions 121 and 122 correspond to the source region and the drain region of the charge transfer section 102. The transfer gate 140 is disposed on the front surface side of the semiconductor substrate 11 and is configured in a columnar shape partially embedded in the semiconductor substrate 11. In addition, the transfer gate 140 is configured to have a depth at which the bottom portion reaches the vicinity of the n-type semiconductor region 121. When an on-voltage is applied to the transfer gate 140, a channel is formed in the semiconductor region on the surface of the transfer gate 140, and the n-type semiconductor regions 121 and 122 are brought into a conductive state. That is, conduction is established between the photoelectric conversion section 101 and the charge holding section 103, and the charge of the photoelectric conversion section 101 is transferred to the charge holding section 103. In this manner, the charge transfer section 102 transfers the charge in the thickness direction of the semiconductor substrate 11. The transfer gate 140 can be constituted by polycrystalline silicon containing impurities. Note that the semiconductor region 121 is an example of a “first semiconductor region” in the present disclosure. The semiconductor region 122 is an example of a “second semiconductor region” of the present disclosure.

The insulating films 190 and 191 are disposed on the front surface side and the back surface side of the semiconductor substrate 11, respectively. The insulating films 190 and 191 can be constituted by, for example, silicon oxide (SiO₂) or silicon nitride (SiN). Note that the insulating film 190 between the transfer gate 140 and the semiconductor substrate 11 corresponds to a gate insulating film.

The separation section 131 and the separation section 132 are arranged at the boundary of the pixels 12 to separate the pixels 12. The separation section 131 is formed in a shape penetrating from the vicinity of the front surface of the semiconductor substrate 11 to the back surface side. Further, the separation section 132 is disposed in the vicinity of the surface of the semiconductor substrate 11. The separation section 131 and the separation section 132 can be configured by embedding an insulator such as SiO₂ in a groove portion formed in the semiconductor substrate 11. Note that a semiconductor region (not illustrated) configured to have a high impurity concentration is disposed in the semiconductor substrate 11 adjacent to the separation section 131. This semiconductor region is a pinning region for pinning the interface state of the semiconductor substrate 11.

The separation section 133 separates elements arranged in the pixel 12. The separation section 133 can be configured by an STI. Note that the separation section 132 can have the same configuration as the separation section 133.

The wiring region 160 is a region that is disposed on the front surface side of the semiconductor substrate 11 and in which wiring for transmitting signals and the like of elements is disposed. The wiring region 160 in the drawing includes an insulating layer 161. The insulating layer 161 insulates an electrode, wiring, and the like disposed on the front surface side of the semiconductor substrate 11. The insulating layer 161 can be constituted by, for example, SiO₂.

The semiconductor substrate 21 is a semiconductor substrate on which a pixel circuit 22 is disposed. The semiconductor substrate 21 is laminated on the semiconductor substrate 11. The back surface of the semiconductor substrate 21 is bonded to the surface of the wiring region 160 of the semiconductor substrate 11, and the semiconductor substrates 11 and 21 are laminated. Similarly to the semiconductor substrate 11, the semiconductor substrate 21 can be constituted by Si. As described above, a reset transistor 104 (corresponding to RST in FIG. 3), an amplification transistor (corresponding to AMP in FIG. 3) (not illustrated), and a selection transistor (corresponding to SEL in FIG. 3) (not illustrated), which constitute the pixel circuit 22, are disposed on the semiconductor substrate 21. In the drawing, the reset transistor 104 is illustrated. In the semiconductor substrate 21 of the drawing, a gate electrode 241 and a semiconductor region 221 constituting the source and the drain of the reset transistor 104 are illustrated. In addition, an insulating film (not illustrated) is disposed on the front surface of the semiconductor substrate 21.

The wiring region 260 is a wiring region disposed on the front surface side of the semiconductor substrate 21. The wiring region 260 includes a wiring 262, a via plug 263, a contact plug 264, and an insulating layer 261.

Similarly to the insulating layer 161, the insulating layer 261 insulates wiring and the like. The insulating layer 261 can be constituted by, for example, SiO₂.

The wiring 262 transmits a signal or the like to the element of the pixel 12. The wiring 262 can be constituted by metal such as copper (Cu) or W, for example. The via plug 263 electrically connects the wirings 262 arranged in different layers. The via plug 263 can be constituted by, for example, columnar Cu. The contact plug 264 electrically connects the wiring 262 to the semiconductor region and the gate electrode of the semiconductor substrate 21. The contact plug 264 can be constituted by, for example, a columnar W or the like.

Note that the through wiring 265 is connected to the wiring 262 in the drawing. As described above, the through wiring 265 is a wiring that connects the transfer gate 140 of the charge transfer section 102 and the semiconductor region 122 of the charge holding section 103 to the wiring 262. The through wiring 265 is formed in a shape penetrating the semiconductor substrate 21. Specifically, the through wiring 265 is disposed in an opening penetrating the semiconductor substrate 21, and is insulated from the semiconductor substrate 21 by the insulating layer 261.

The color filter 192 is an optical filter that transmits light of a predetermined wavelength among the incident light. As the color filter 192, for example, a color filter that transmits red light, green light, and blue light can be used.

The on-chip lens 193 is a lens that condenses incident light. The on-chip lens 193 is formed in, for example, a hemispherical shape, and condenses incident light on the photoelectric conversion section 101.

### [Configuration of Charge Transfer Section]

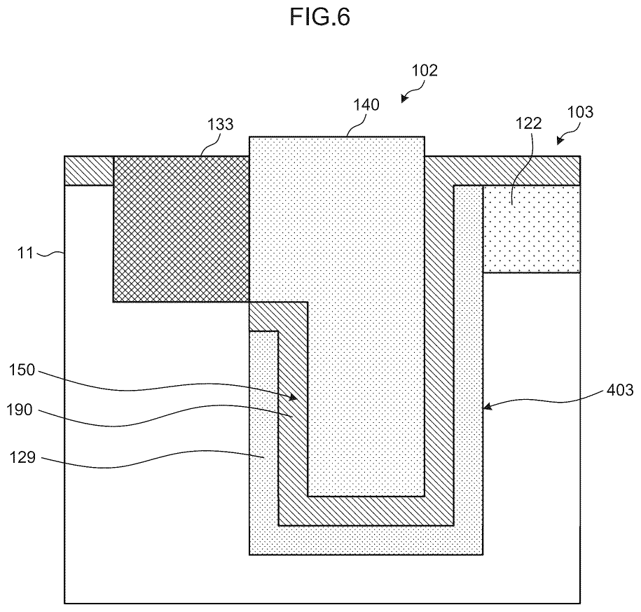

FIG. 6 is a diagram illustrating a configuration example of a charge transfer section according to the first embodiment of the present disclosure. The drawing is a schematic cross-sectional view illustrating a configuration example of the charge transfer section 102. As described above, the transfer gate 140 is disposed in the charge transfer section 102. The transfer gate 140 is disposed adjacent to the separation section 133. The insulating film 190 and a channel region 129 constituting the gate insulating film are arranged adjacent to the region of the transfer gate 140 other than the region in contact with the separation section 133.

The channel region 129 is a region in which a channel for transferring charge is formed. The channel region 129 is a semiconductor region formed by epitaxial growth of a recess 403 formed on the surface of the semiconductor substrate 11 from the surface of the semiconductor substrate 11. The channel region 129 can be configured to have an impurity concentration different from that of the well region of the semiconductor substrate 11. Even in a case where the pixel 12 is miniaturized, the impurity concentration in the region where the channel is formed can be adjusted without being affected by impurities in other regions of the semiconductor substrate 11. The insulating film 190 described above is disposed between the transfer gate 140 and the channel region 129.

In addition, the notch portion 150 is disposed at the bottom portion of the transfer gate 140. The notch portion 150 is formed on a side surface adjacent to the separation section 133. The drawing illustrates an example in which the channel region 129 and the insulating film 190 are disposed in the notch portion 150. By arranging such a notch portion 150, the transfer gate 140 can be separated from the pinning region. As a result, the influence of impurities in the pinning region can be reduced, and the characteristics of the charge transfer section 102 can be stabilized. In addition, the transfer gate 140 can be miniaturized by forming the notch portion 150.

### [Method for Manufacturing Photodetection Apparatus]

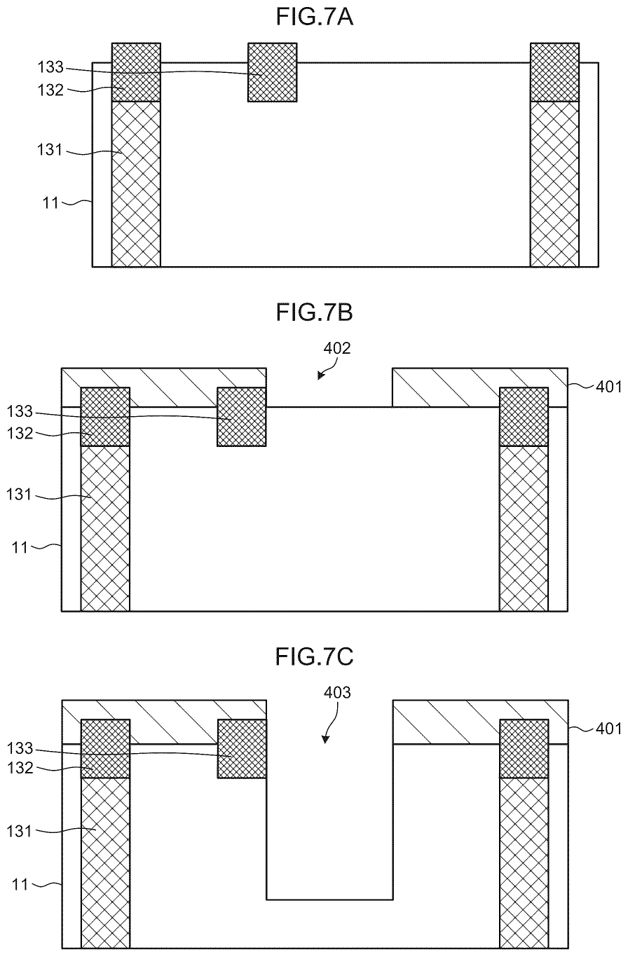

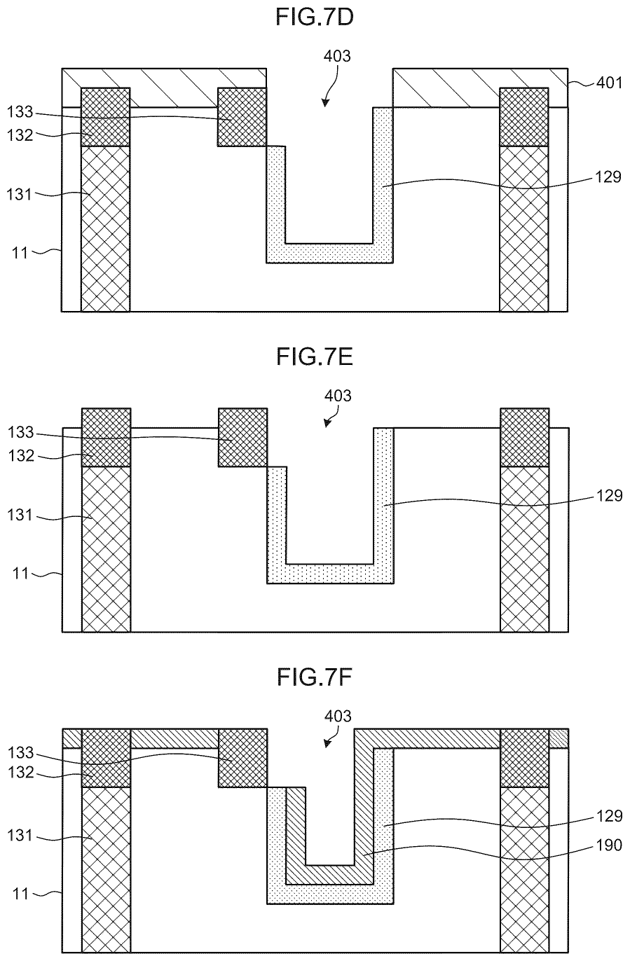

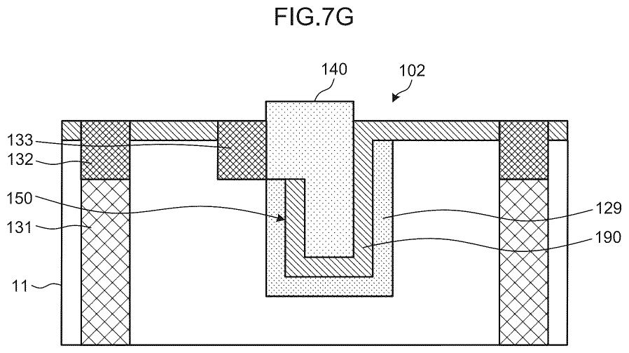

FIGS. 7A to 7G are diagrams illustrating an example of a method for manufacturing the photodetection apparatus according to the first embodiment of the present disclosure. The drawing is a diagram illustrating an example of a method for manufacturing the semiconductor substrate 11 portion according to the pixel 12 in the manufacturing process of the photodetection apparatus 1.

First, the separation section 131 is formed in the semiconductor substrate 11. This can be performed by forming a groove-shaped opening penetrating the semiconductor substrate 11 and arranging an insulator or the like. Next, a pinning region (not illustrated) is formed in the semiconductor substrate 11 in the vicinity of the separation section 131. This can be performed, for example, by ion implantation. Next, the separation section 132 and the separation section 133 are formed. This can be performed by forming a recess on the front surface side of the semiconductor substrate 11 and disposing an insulator. FIG. 7A is a diagram illustrating the semiconductor substrate 11 on which the separation sections 131 to 133 are formed.

Next, a mask 401 is disposed on the surface of the semiconductor substrate 11 (FIG. 7B). In the mask 401, an opening 402 is arranged in a region where the transfer gate 140 and the channel region 129 are formed. The mask 401 can be constituted by SiN, for example.

Next, a recess 403 is formed on the surface of the semiconductor substrate 11 (FIG. 7C). This can be performed by etching the semiconductor substrate 11 through the opening 402 of the mask 401.

Next, the channel region 129 is formed (FIG. 7D). This can be performed by forming a semiconductor region on the surface of the semiconductor substrate 11 of the recess 403 by epitaxial growth. Next, the mask 401 is removed (FIG. 7E).

Next, the insulating film 190 is formed on the surface of the semiconductor substrate 11 including the recess 403 (FIG. 7F). This can be performed by thermal oxidation or plasma oxidation of the semiconductor substrate 11.

Next, the transfer gate 140 is formed (FIG. 7G). This can be performed by disposing a material film of the transfer gate 140 on the surface of the semiconductor substrate 11 including the recess 403 and removing an unnecessary portion. Through the above steps, the photodetection apparatus 1 can be manufactured.

As described above, in the photodetection apparatus 1 according to the first embodiment of the present disclosure, the transfer gate 140 having a shape in contact with the separation section 133 can be arranged in the charge transfer section 102. Furthermore, by forming the notch portion 150 in the transfer gate 140, the transfer gate 140 can be separated from the pinning region at the end portion of the pixel 12. Therefore, even in a case where the charge transfer section 102 is brought close to the separation section 132 or the separation section 133, it is possible to reduce the influence of performance deterioration or the like of the charge transfer section 102. As a result, the size of the pixel 12 can be reduced.

### 2. Second Embodiment

In the photodetection apparatus 1 of the first embodiment described above, the channel region 129 is formed outside the transfer gate 140 of the charge transfer section 102. On the other hand, a photodetection apparatus 1 according to a second embodiment of the present disclosure is different from that of the above-described first embodiment in that an inclined surface is formed at an end portion of the channel region 129.

### [Configuration of Charge Transfer Section]

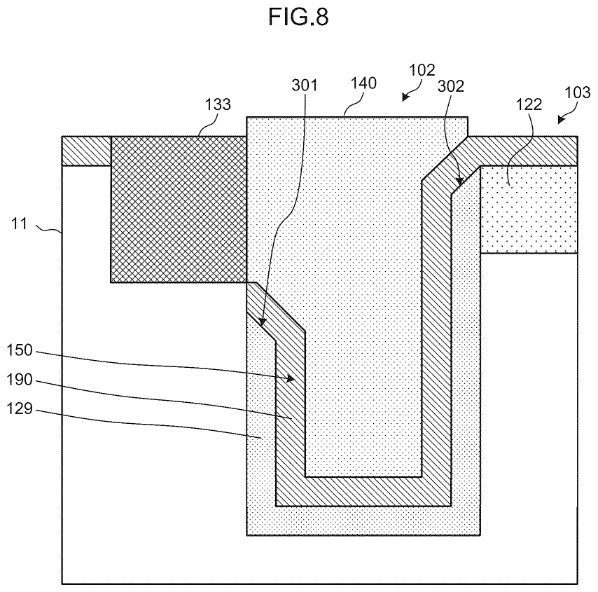

FIG. 8 is a diagram illustrating a configuration example of a charge transfer section according to the second embodiment of the present disclosure. The drawing is a schematic cross-sectional view illustrating a configuration example of the charge transfer section 102, similarly to FIG. 6. The charge transfer section 102 in the drawing is different from the photodetection apparatus 1 in FIG. 1 in that an inclined surface is formed at an end portion of the channel region 129.

In the channel region 129 in the drawing, inclined surfaces 301 and 302 are formed at end portions. This inclined surface is a facet surface formed on the basis of the plane orientation of the semiconductor substrate 21. By disposing the inclined surfaces 301 and 302, thinning of the insulating film 190 in the vicinity of the end portion of the channel region 129 can be prevented, and electric field concentration in the thinned insulating film 190 can be prevented. This makes it possible to prevent occurrence of a leakage current due to a strong electric field, and to prevent occurrence of an error in an image signal due to the leakage current.

In addition, the transfer gate 140 may be configured in a shape extending in a region outside the inclined surfaces 301 and 302 on the surface of the semiconductor substrate 11. In this case, it is possible to avoid a residue trouble due to the recess at the electrode end in a process after the formation of the transfer gate 140. In addition, since the region of the transfer gate 140 can be expanded, connection with the through wiring 265 can be facilitated.

### [Method for Manufacturing Photodetection Apparatus]

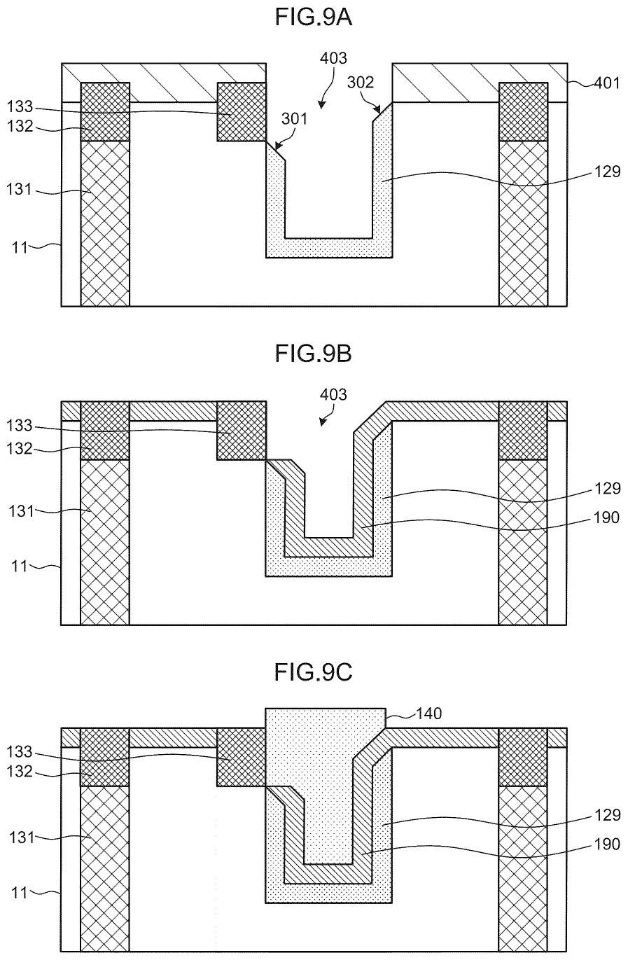

FIGS. 9A to 9C are diagrams illustrating an example of a method for manufacturing the photodetection apparatus according to the second embodiment of the present disclosure. The drawing is a diagram illustrating an example of a method for manufacturing the semiconductor substrate 11 portion according to the pixel 12 in the manufacturing process of the photodetection apparatus 1.

First, the recess 403 is formed in the semiconductor substrate 11 by the steps of FIGS. 7A to 7C. Next, the channel region 129 is formed by epitaxial growth. At this time, the inclined surfaces 301 and 302 based on the plane orientation of the semiconductor substrate 21 are grown in a region adjacent to the recess 403 (FIG. 9A).

Next, the insulating film 190 is formed on the surface of the semiconductor substrate 11 including the recess 403 by a step similar to that in FIG. 7F (FIG. 9B). Next, the transfer gate 140 is formed by a step similar to that in FIG. 7G (FIG. 9C). Through the above steps, the photodetection apparatus 1 can be manufactured.

Since the configuration of the photodetection apparatus 1 other than this is similar to the configuration of the photodetection apparatus 1 in the first embodiment of the present disclosure, the description thereof will be omitted.

As described above, in the photodetection apparatus 1 according to the second embodiment of the present disclosure, by forming the inclined surfaces 301 and 302 at the end portion of the channel region 129 of the charge transfer section 102, thinning of the insulating film 190 in the vicinity of the end portion of the channel region 129 can be prevented. As a result, the error of the image signal can be reduced.

### 3. Third Embodiment

In the photodetection apparatus 1 of the first embodiment described above, the channel region 129 is arranged around the transfer gate 140. On the other hand, a photodetection apparatus 1 according to a third embodiment of the present disclosure is different from that of the above-described first embodiment in that a region where the channel region 129 is generated is adjusted.

### [Configuration of Charge Transfer Section]

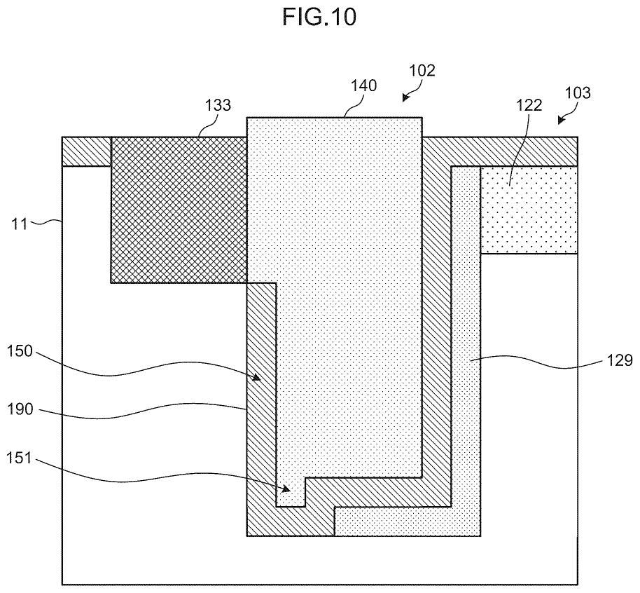

FIG. 10 is a diagram illustrating a configuration example of a charge transfer section according to the third embodiment of the present disclosure. The drawing is a schematic cross-sectional view illustrating a configuration example of the charge transfer section 102, similarly to FIG. 6. The charge transfer section 102 in the drawing is different from the photodetection apparatus 1 in FIG. 6 in that a region where the channel region 129 is formed is adjusted.

The channel region 129 in the drawing is formed in a region other than the surface adjacent to the separation section 133 of the transfer gate 140 and the bottom surface adjacent to the surface. In addition, by limiting the region where the channel region 129 is formed, a protrusion 151 can be formed at the bottom portion of the transfer gate 140. It is possible to concentrate charges with the protrusion 151 as a starting point. As a result, it is possible to reduce the fluctuation in the characteristics based on the change in the shape of the transfer gate 140.

The notch portion 150 in the drawing illustrates an example in which the insulating film 190 is disposed.

### [Method for Manufacturing Photodetection Apparatus]

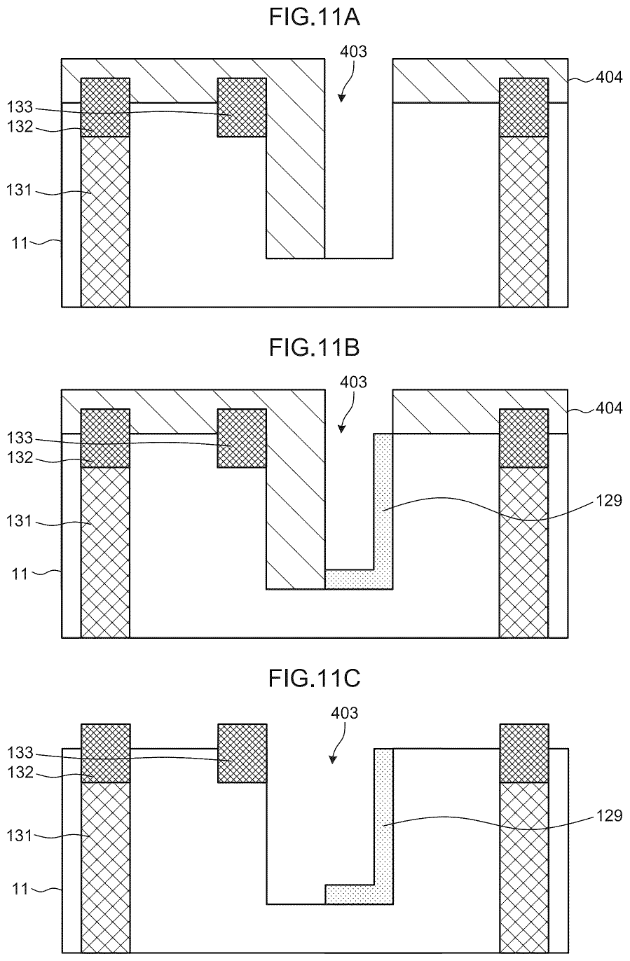

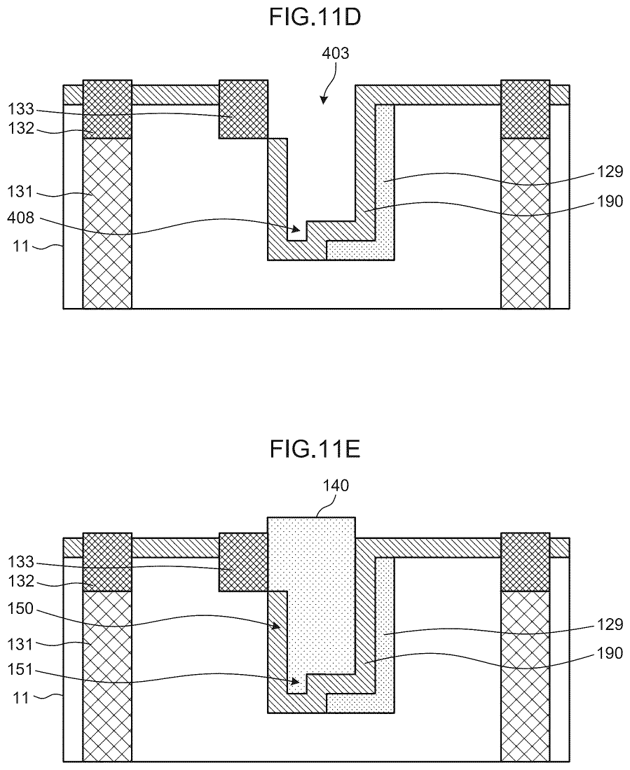

FIGS. 11A to 11E are diagrams illustrating an example of a method for manufacturing the photodetection apparatus according to the third embodiment of the present disclosure. The drawing is a diagram illustrating an example of a method for manufacturing the semiconductor substrate 11 portion according to the pixel 12 in the manufacturing process of the photodetection apparatus 1.

First, the recess 403 is formed in the semiconductor substrate 11 by the steps of FIGS. 7A to 7C, and the mask 401 is removed. Next, a mask 404 is disposed (FIG. 11A). The mask 404 is formed in a shape that covers a surface of the recess 403 including the separation section 133.

Next, the channel region 129 is formed by a step similar to that in FIG. 7D (FIG. 11B). As illustrated in the drawing, the region where the channel region 129 is formed can be adjusted according to the shape of the mask 404.

Next, the mask 404 is removed (FIG. 11C). Next, the insulating film 190 is formed by a step similar to that in FIG. 7F (FIG. 11D). At this time, the recess 403 is generated in the insulating film 190 at the bottom portion of a recess 408. Next, the transfer gate 140 is formed by a step similar to that in FIG. 7G (FIG. 11E). A material film of the transfer gate 140 is disposed in the recess 408, and the protrusion 151 is formed. Through the above steps, the photodetection apparatus 1 can be manufactured.

Since the configuration of the photodetection apparatus 1 other than this is similar to the configuration of the photodetection apparatus 1 in the first embodiment of the present disclosure, the description thereof will be omitted.

As described above, the photodetection apparatus 1 according to the third embodiment of the present disclosure can adjust the region where the channel region 129 is formed and optimize the shape of the channel region 129.

### 4. Fourth Embodiment

In the photodetection apparatus 1 of the third embodiment described above, the region where the channel region 129 is formed is adjusted. On the other hand, a photodetection apparatus 1 according to a fourth embodiment of the present disclosure is different from the above-described third embodiment in that an inclined surface is formed at an end portion of the channel region 129.

### [Configuration of Charge Transfer Section]

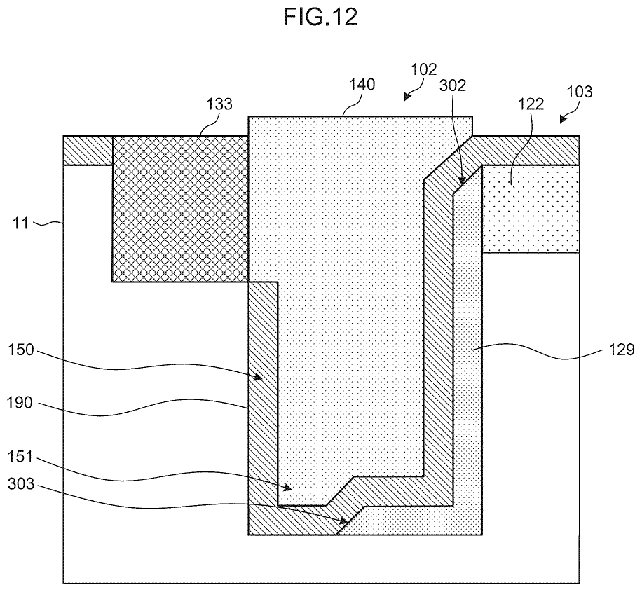

FIG. 12 is a diagram illustrating a configuration example of a charge transfer section according to the fourth embodiment of the present disclosure. The drawing is a schematic cross-sectional view illustrating a configuration example of the charge transfer section 102, similarly to FIG. 10. The charge transfer section 102 in the drawing is different from the photodetection apparatus 1 in FIG. 10 in that an inclined surface is formed at an end portion.

The channel region 129 in the drawing is different from the channel region 129 in FIG. 10 in that inclined surfaces 302 and 303 are formed at end portions. This inclined surface is a facet surface formed on the basis of the plane orientation of the semiconductor substrate 21. By forming the inclined surfaces 302 and 303 at the end portion of the channel region 129, it is possible to prevent thinning of the insulating film 190 in the vicinity of the end portion, similarly to the channel region 129 of FIG. 8.

### [Method for Manufacturing Photodetection Apparatus]

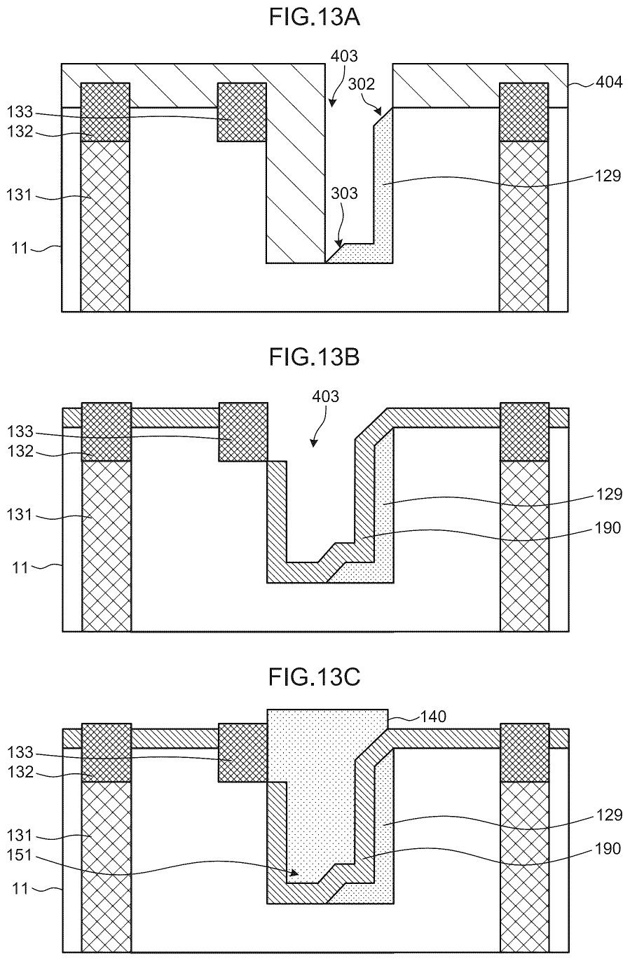

FIGS. 13A to 13C are diagrams illustrating an example of a method for manufacturing the photodetection apparatus according to the fourth embodiment of the present disclosure. The drawing is a diagram illustrating an example of a method for manufacturing the semiconductor substrate 11 portion according to the pixel 12 in the manufacturing process of the photodetection apparatus 1.

First, the recess 403 is formed in the semiconductor substrate 11 by the step of FIG. 11A, and the mask 404 is disposed. Next, the channel region 129 is formed by a step similar to that in FIG. 9A (FIG. 13A). As a result, the channel region 129 having the inclined surfaces 302 and 303 can be formed.

Next, the mask 404 is removed, and the insulating film 190 is formed by a step similar to that in FIG. 7F (FIG. 13B). Next, the transfer gate 140 is formed by a step similar to that in FIG. 7G (FIG. 13C). As a result, the material film of the transfer gate 140 is disposed in the recess 408, and the protrusion 151 is formed. Through the above steps, the photodetection apparatus 1 can be manufactured.

Since the configuration of the photodetection apparatus 1 other than this is similar to the configuration of the photodetection apparatus 1 in the third embodiment of the present disclosure, the description thereof will be omitted.

As described above, in the photodetection apparatus 1 according to the fourth embodiment of the present disclosure, by forming the inclined surfaces 302 and 303 at the end portion of the channel region 129 of the charge transfer section 102, thinning of the insulating film 190 in the vicinity of the end portion of the channel region 129 can be prevented. As a result, the error of the image signal can be reduced.

### 5. Fifth Embodiment

In the photodetection apparatus 1 of the first embodiment described above, the channel region 129 and the insulating film 190 are arranged in the notch portion 150 of the transfer gate 140 of the charge transfer section 102. On the other hand, a photodetection apparatus 1 according to a fifth embodiment of the present disclosure is different from the photodetection apparatus 1 according to the first embodiment described above in that a semiconductor region of the semiconductor substrate 11 is further disposed in the notch portion 150.

### [Configuration of Charge Transfer Section]

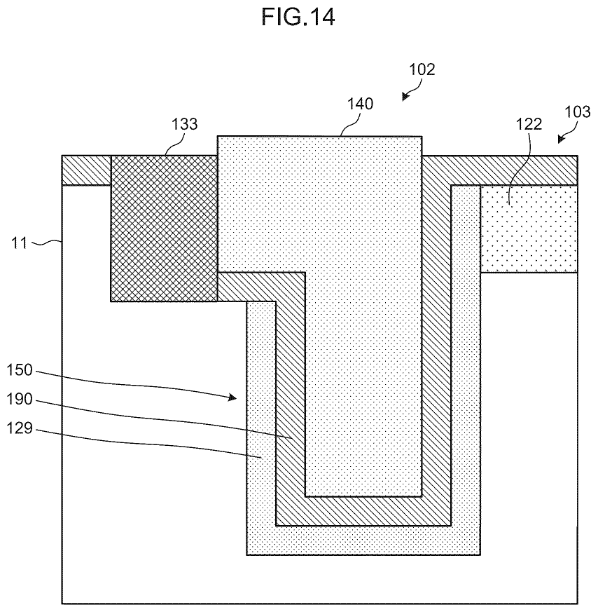

FIG. 14 is a diagram illustrating a configuration example of a charge transfer section according to the fifth embodiment of the present disclosure. The drawing is a schematic cross-sectional view illustrating a configuration example of the charge transfer section 102, similarly to FIG. 6. The charge transfer section 102 in the drawing is different from the photodetection apparatus 1 in FIG. 6 in that the insulating film 190, the channel region 129, and the semiconductor region are arranged in the notch portion 150.

The separation section 133 in the drawing is thinner than the separation section 133 in FIG. 6, and the size thereof is reduced in the left direction in the drawing. The transfer gate 140 in the drawing is formed in a shape extending in a region where the separation section 133 is reduced. As a result, the notch portion 150 is formed in a shape including the semiconductor region outside the channel region 129. Since the region of the transfer gate 140 can be expanded, connection with the through wiring 265 can be facilitated.

### [Method for Manufacturing Photodetection Apparatus]

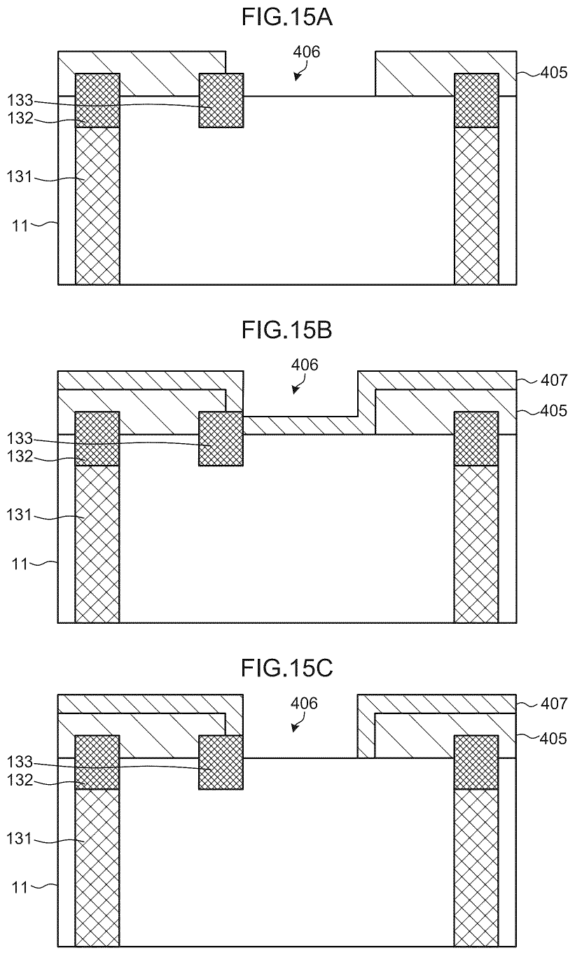

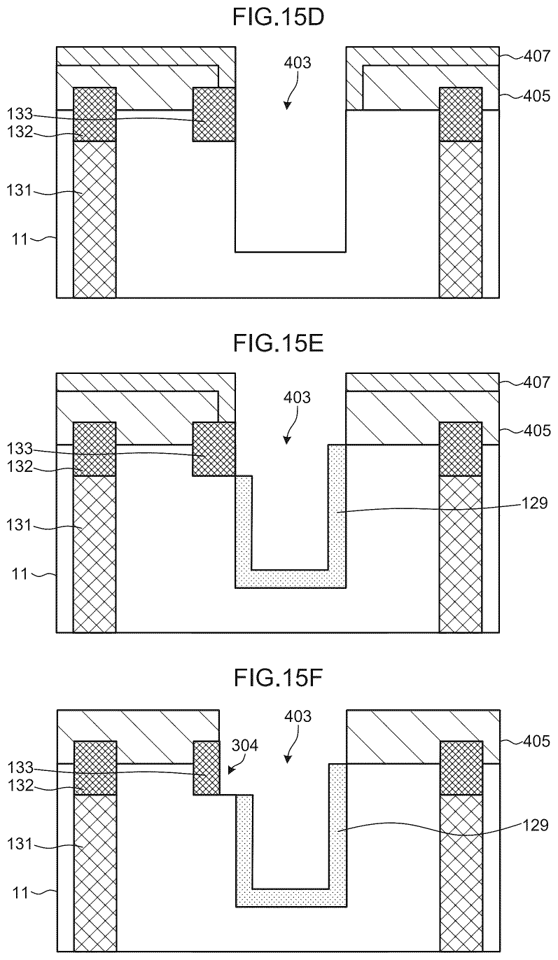

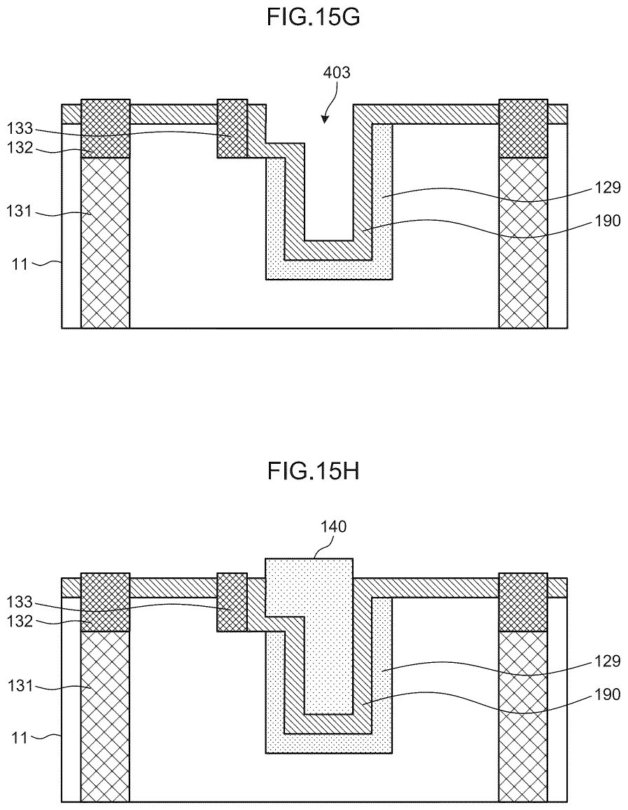

FIGS. 15A to 15H are diagrams illustrating an example of a method for manufacturing the photodetection apparatus according to the fifth embodiment of the present disclosure. The drawing is a diagram illustrating an example of a method for manufacturing the semiconductor substrate 11 portion according to the pixel 12 in the manufacturing process of the photodetection apparatus 1.

First, the separation sections 131 to 133 are formed in the semiconductor substrate 11. Next, a mask 405 is disposed on the surface of the semiconductor substrate 11 (FIG. 15A). In the mask 405, an opening 406 is arranged in a region forming the channel region 129. Furthermore, the mask 405 can be constituted by SiN.

Next, a mask 407 is disposed on the surface of the semiconductor substrate 11 including the opening 406 (FIG. 15B). The mask 407 can be constituted by the same member as the separation section 133, for example, SiO₂.

Next, the mask 407 at the bottom portion of the opening 406 is removed (FIG. 15C).

Next, the recess 403 is formed on the surface of the semiconductor substrate 11 (FIG. 15D). This can be performed by etching the semiconductor substrate 11 through the openings 406 of the masks 405 and 407.

Next, the channel region 129 is formed by a step similar to that in FIG. 7D (FIG. 15E).

Next, the mask 407 is removed (FIG. 15F). This can be performed by etching the mask 407. At this time, a part of the separation section 133 is etched, and the notch portion 304 is formed in the semiconductor substrate 11.

Next, the insulating film 190 is formed by a step similar to that in FIG. 7F (FIG. 15G). Next, the transfer gate 140 is formed by a step similar to that in FIG. 7G (FIG. 15H). At this time, the material film of the transfer gate 140 is disposed in the notch portion 304. Through the above steps, the photodetection apparatus 1 can be manufactured.

Since the configuration of the photodetection apparatus 1 other than this is similar to the configuration of the photodetection apparatus 1 in the first embodiment of the present disclosure, the description thereof will be omitted.

As described above, the photodetection apparatus 1 according to the fifth embodiment of the present disclosure can expand the transfer gate 140 of the charge transfer section 102. Accordingly, connection with the through wiring 265 can be easily performed.

### 6. Sixth Embodiment

In the photodetection apparatus 1 of the above-described fifth embodiment, the insulating film 190, the channel region 129, and the semiconductor region of the semiconductor substrate 11 are arranged in the notch portion 150 of the transfer gate 140 of the charge transfer section 102. On the other hand, a photodetection apparatus 1 according to a sixth embodiment of the present disclosure is different from the above-described fifth embodiment in that an inclined surface is formed at an end portion of the channel region 129.

### [Configuration of Charge Transfer Section]

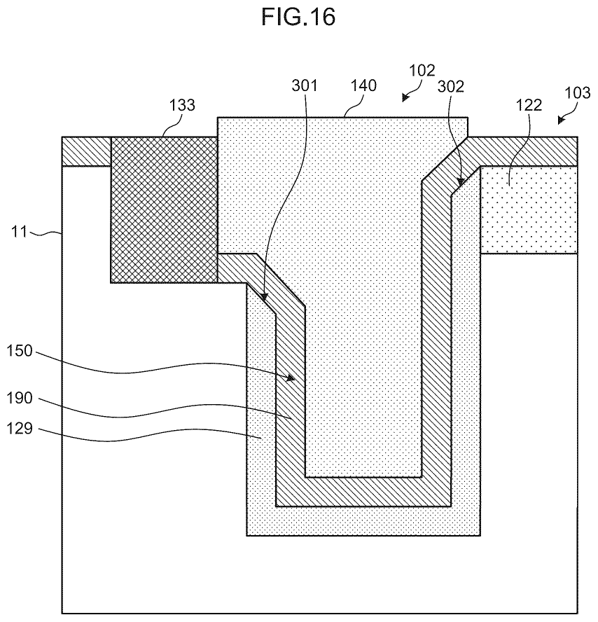

FIG. 16 is a diagram illustrating a configuration example of a charge transfer section according to the sixth embodiment of the present disclosure. The drawing is a schematic cross-sectional view illustrating a configuration example of the charge transfer section 102, similarly to FIG. 14. The charge transfer section 102 in the drawing is different from the photodetection apparatus 1 in FIG. 14 in that the inclined surfaces 301 and 302 are formed at the end portion of the channel region 129.

### [Method for Manufacturing Photodetection Apparatus]

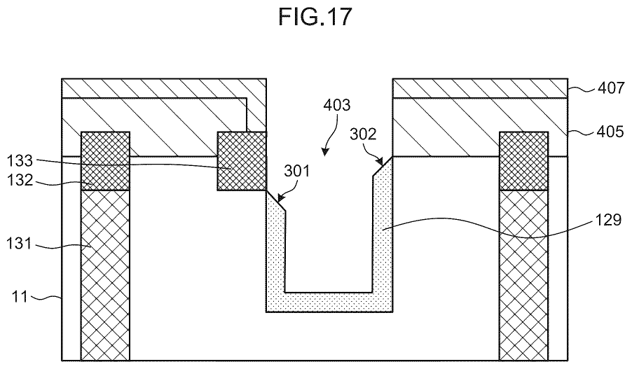

FIG. 17 is a diagram illustrating an example of a method for manufacturing the photodetection apparatus according to the sixth embodiment of the present disclosure. The drawing is a diagram illustrating an example of a method for manufacturing the semiconductor substrate 11 portion according to the pixel 12 in the manufacturing process of the photodetection apparatus 1.

First, by the steps of FIGS. 15A to 15D, the separation sections 131 to 133 are formed in the semiconductor substrate 11, the masks 405 and 407 are arranged, and the recess 403 is formed. Next, the channel region 129 is formed by a step similar to that in FIG. 9A (FIG. 17). As a result, the inclined surfaces 301 and 302 can be formed at the end portion of the channel region 129. Thereafter, the steps of FIGS. 15F to 15H are executed. Through the above steps, the photodetection apparatus 1 can be manufactured.

Since the configuration of the photodetection apparatus 1 other than this is similar to the configuration of the photodetection apparatus 1 in the fifth embodiment of the present disclosure, the description thereof will be omitted.

As described above, in the photodetection apparatus 1 of the sixth embodiment of the present disclosure, by forming the inclined surfaces 301 and 302 at the end portion of the channel region 129 of the charge transfer section 102, thinning of the insulating film 190 in the vicinity of the end portion of the channel region 129 can be prevented. As a result, the error of the image signal can be reduced.

### 7. Seventh Embodiment

In the photodetection apparatus 1 of the above-described fifth embodiment, the insulating film 190, the channel region 129, and the semiconductor region of the semiconductor substrate 11 are arranged in the notch portion 150 of the transfer gate 140 of the charge transfer section 102. On the other hand, a photodetection apparatus 1 according to a seventh embodiment of the present disclosure is different from that of the above-described fifth embodiment in that a region where the channel region 129 is generated is adjusted.

### [Configuration of Charge Transfer Section]

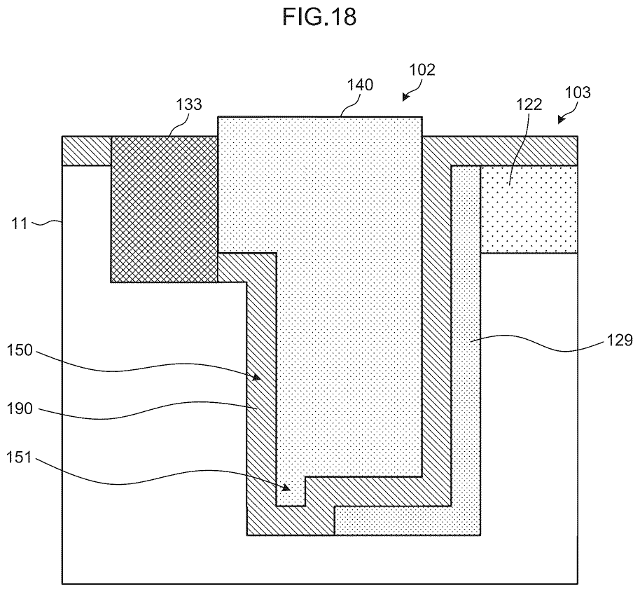

FIG. 18 is a diagram illustrating a configuration example of a charge transfer section according to the seventh embodiment of the present disclosure. The drawing is a schematic cross-sectional view illustrating a configuration example of the charge transfer section 102, similarly to FIG. 14. The charge transfer section 102 in the drawing is different from the photodetection apparatus 1 in FIG. 14 in that a region where the channel region 129 is formed is adjusted.

The channel region 129 in the drawing is formed in a region other than a surface adjacent to the separation section 133 of the transfer gate 140 and a bottom surface adjacent to the surface, similarly to the channel region 129 in FIG. 10.

The notch portion 150 in the drawing illustrates an example in which the insulating film 190 and the semiconductor region of the semiconductor substrate are arranged.

### [Method for Manufacturing Photodetection Apparatus]

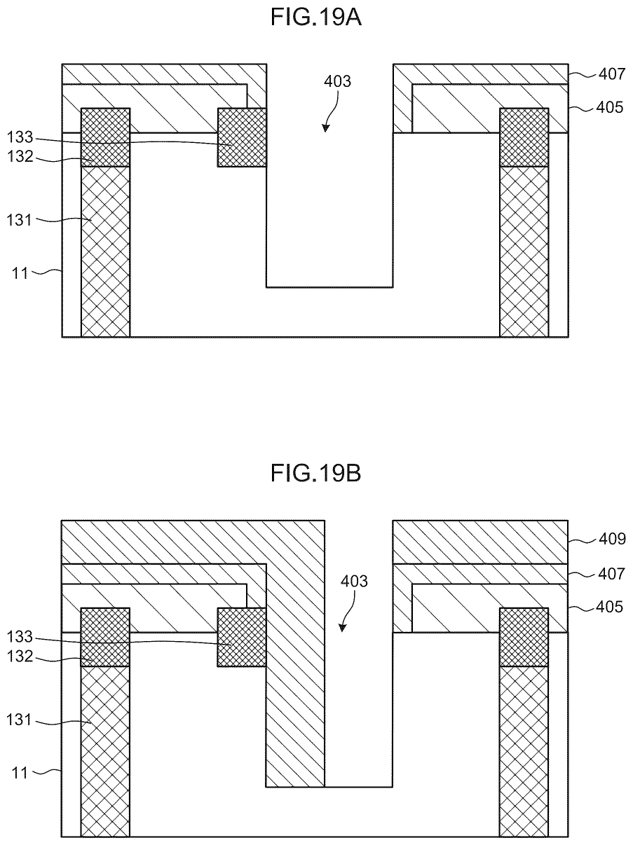

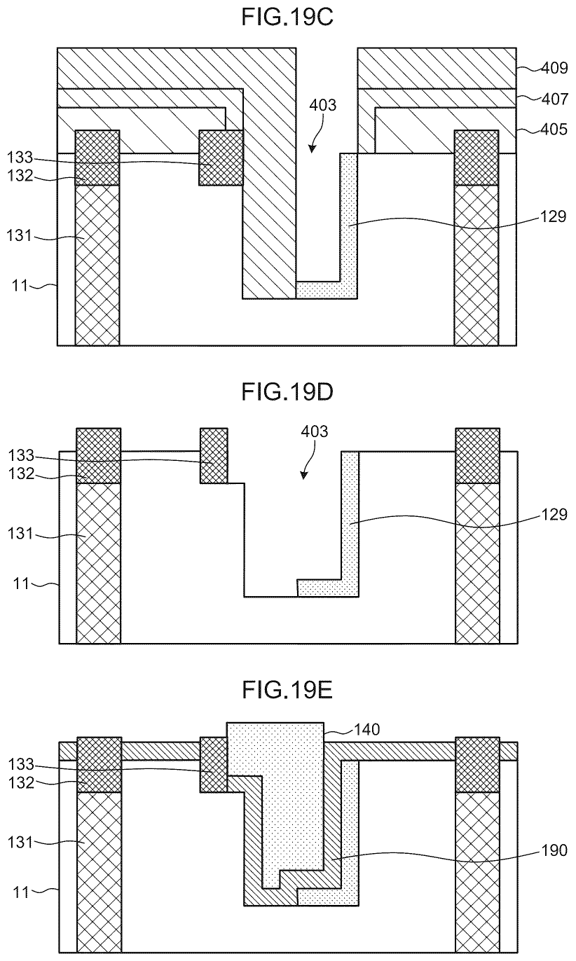

FIGS. 19A to 19E are diagrams illustrating an example of a method for manufacturing the photodetection apparatus according to the seventh embodiment of the present disclosure. The drawing is a diagram illustrating an example of a method for manufacturing the semiconductor substrate 11 portion according to the pixel 12 in the manufacturing process of the photodetection apparatus 1.

First, by the steps of FIGS. 15A to 15D, the separation sections 131 to 133 are formed in the semiconductor substrate 11, the masks 405 and 407 are arranged, and the recess 403 is formed (FIG. 19A). Next, a mask 409 having a shape similar to the mask 404 of FIG. 11A is formed (FIG. 19B). Next, the channel region 129 is formed by a step similar to that in FIG. 7D (FIG. 19C). Next, the masks 405, 407, and 409 are removed (FIG. 19D). Next, the insulating film 190 and the transfer gate 140 are arranged by a step similar to that in FIG. 7G (FIG. 19E). Through the above steps, the photodetection apparatus 1 can be manufactured.

Since the configuration of the photodetection apparatus 1 other than this is similar to the configuration of the photodetection apparatus 1 in the fifth embodiment of the present disclosure, the description thereof will be omitted.

As described above, the photodetection apparatus 1 according to the seventh embodiment of the present disclosure can adjust the region where the channel region 129 is formed and optimize the shape of the channel region 129.

### 8. Eighth Embodiment

In the photodetection apparatus 1 of the above-described seventh embodiment, the region where the channel region 129 of the charge transfer section 102 is generated is adjusted. On the other hand, a photodetection apparatus 1 according to an eighth embodiment of the present disclosure is different from that of the above-described seventh embodiment in that a region where an inclined surface is formed at an end portion of the channel region 129 is adjusted.

### [Configuration of Charge Transfer Section]

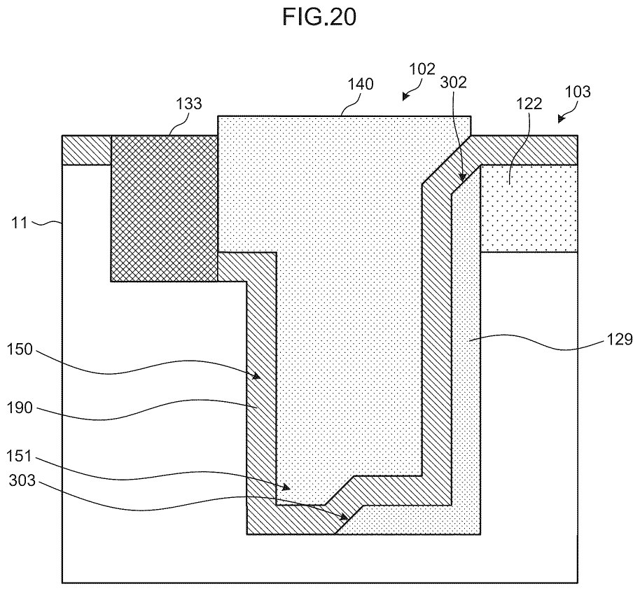

FIG. 20 is a diagram illustrating a configuration example of a charge transfer section according to the eighth embodiment of the present disclosure. The drawing is a schematic cross-sectional view illustrating a configuration example of the charge transfer section 102, similarly to FIG. 18. The charge transfer section 102 in the drawing is different from the photodetection apparatus 1 in FIG. 18 in that a region where an inclined surface is formed at an end portion of the channel region 129 is adjusted.

In the channel region 129 in the drawing, the inclined surfaces 302 and 303 are formed at end portions.

### [Method for Manufacturing Photodetection Apparatus]

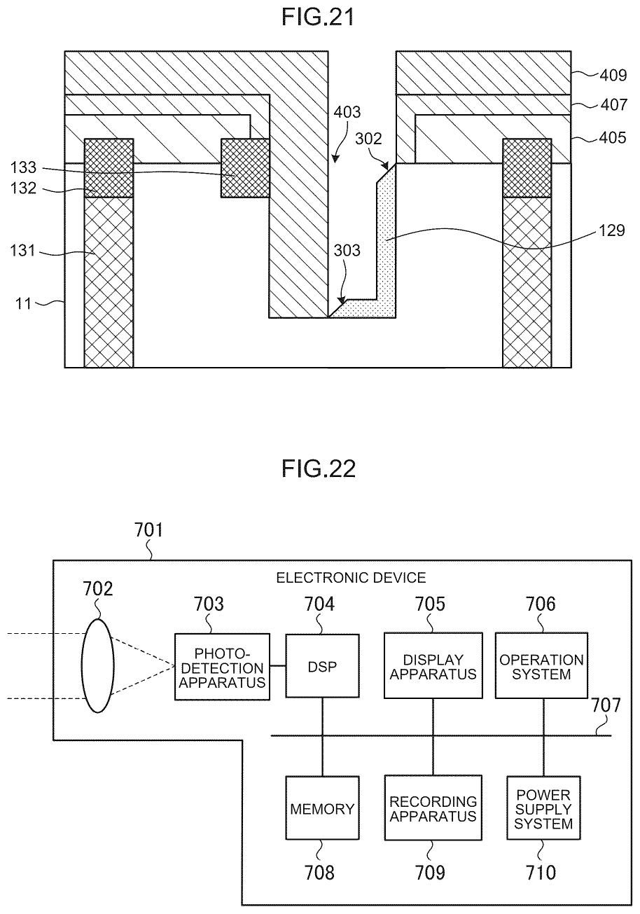

FIG. 21 is a diagram illustrating an example of a method for manufacturing the photodetection apparatus according to the eighth embodiment of the present disclosure. The drawing is a diagram illustrating an example of a method for manufacturing the semiconductor substrate 11 portion according to the pixel 12 in the manufacturing process of the photodetection apparatus 1.

First, by the steps of FIGS. 19A and 19B, the separation sections 131 to 133 are formed in the semiconductor substrate 11, the masks 405 and 407 are arranged, and the recess 403 is formed. Next, the mask 409 having a shape similar to the mask 404 of FIG. 11A is formed. Next, the channel region 129 is formed by a step similar to that in FIG. 9A (FIG. 21). Thereafter, the steps of FIGS. 19D and 19E are executed. Through the above steps, the photodetection apparatus 1 can be manufactured.

Since the configuration of the photodetection apparatus 1 other than this is similar to the configuration of the photodetection apparatus 1 in the seventh embodiment of the present disclosure, the description thereof will be omitted.

As described above, in the photodetection apparatus 1 of the eighth embodiment of the present disclosure, by forming the inclined surfaces 301 and 302 at the end portion of the channel region 129 of the charge transfer section 102, thinning of the insulating film 190 in the vicinity of the end portion of the channel region 129 can be prevented. As a result, the error of the image signal can be reduced.

### (9. Configuration of Electronic Device)

The photodetection apparatus 1 as described above can be applied to various electronic devices such as an imaging system such as a digital still camera or a digital video camera, a mobile phone having an imaging function, or another device having an imaging function.

FIG. 22 is a block diagram illustrating a configuration example of an imaging apparatus mounted on an electronic device. As illustrated in FIG. 22, an electronic device 701 includes an optical system 702, a photodetection apparatus 703, and a digital signal processor (DSP) 704, and is configured by connecting a DSP 704, a display apparatus 705, an operation system 706, a memory 708, a recording apparatus 709, and a power supply system 710 via a bus 707, and is capable of capturing a still image and a moving image.

The optical system 702 includes one or a plurality of lenses, guides image light (incident light) from a subject to the photodetection apparatus 703, and forms an image on a light receiving surface (sensor section) of the photodetection apparatus 703.

As the photodetection apparatus 703, the photodetection apparatus 1 of any of the above-described configuration examples is applied. In the photodetection apparatus 703, electrons are accumulated for a certain period according to an image formed on the light receiving surface via the optical system 702. Then, a signal corresponding to the electrons accumulated in the photodetection apparatus 703 is input to the DSP 704.

The DSP 704 performs various types of signal processing on the signal from the photodetection apparatus 703 to acquire an image, and temporarily stores data of the image in the memory 708. The image data stored in the memory 708 is recorded in the recording apparatus 709 or supplied to the display apparatus 705 to display an image. In addition, the operation system 706 receives various operations by the user and supplies an operation signal to each block of the electronic device 701, and the power supply system 710 supplies power necessary for driving each block of the electronic device 701.

### (6. Example of Application to Mobile Body)

The technology according to the present disclosure (the present technology) is applicable to various products. For example, the technology according to the present disclosure may be applied to devices mounted on any of mobile body such as automobiles, electric vehicles, hybrid electric vehicles, motorcycles, bicycles, personal mobility, airplanes, drones, ships, and robots.

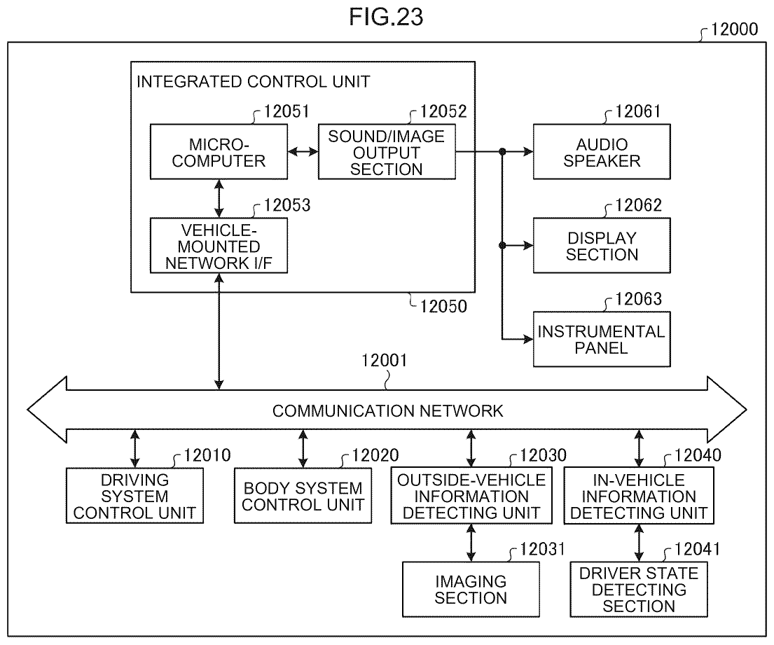

FIG. 23 is a block diagram depicting an example of schematic configuration of a vehicle control system as an example of a mobile body control system to which the technology according to an embodiment of the present disclosure can be applied.

A vehicle control system 12000 includes a plurality of electronic control units connected to each other via a communication network 12001. In the example depicted in FIG. 23, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 23, an audio speaker 12061, a display section 12062, and an instrument panel 12063 are illustrated as the output device. The display section 12062 may, for example, include at least one of an on-board display and a head-up display.

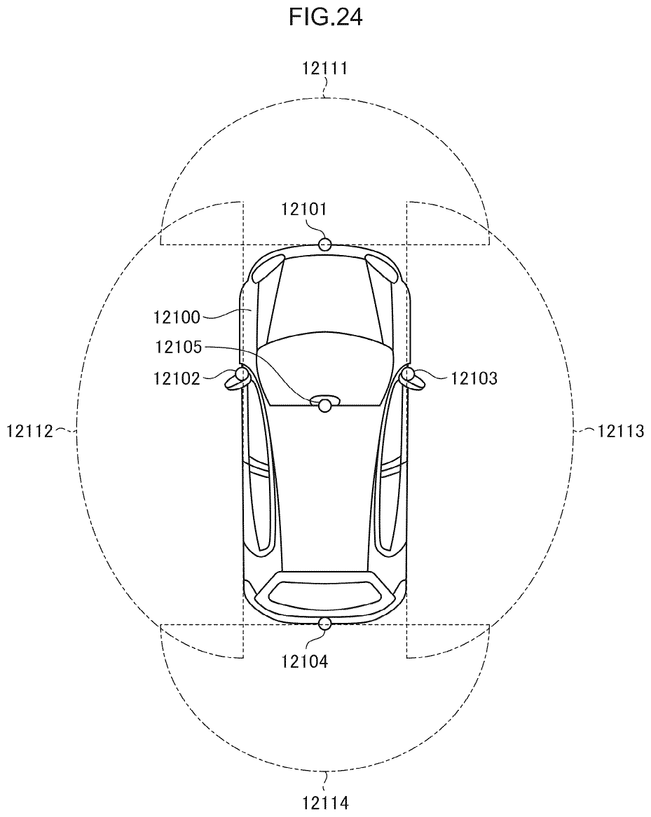

FIG. 24 is a diagram depicting an example of the installation position of the imaging section 12031.

In FIG. 24, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of a vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 24 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 among the configurations described above. Specifically, the photodetection apparatus 1 of FIG. 1 can be applied to the imaging section 12031.

### (11. Example of Application to Endoscopic Surgery System)

The technology according to the present disclosure (the present technology) is applicable to various products. For example, the techniques according to the present disclosure may be applied to endoscopic surgery systems.

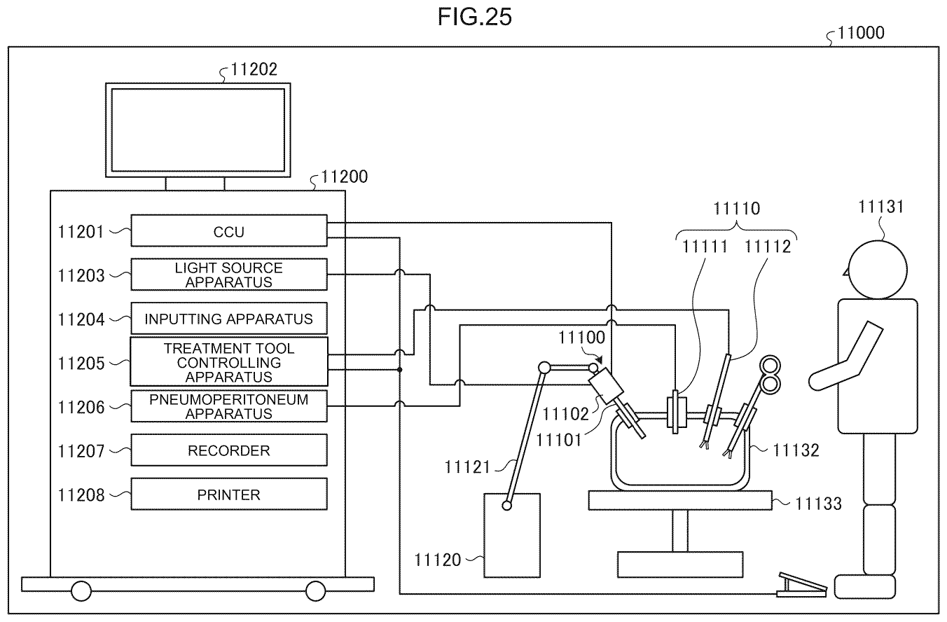

FIG. 25 is a view depicting an example of a schematic configuration of an endoscopic surgery system to which the technology according to an embodiment of the present disclosure (present technology) can be applied.

In FIG. 25, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

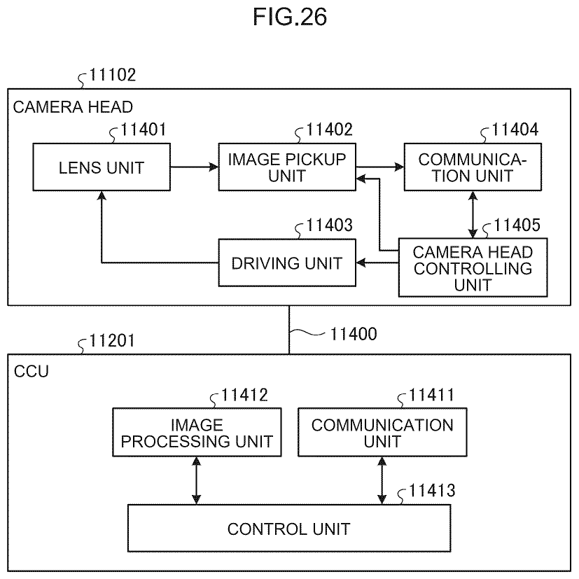

FIG. 26 is a block diagram depicting an example of a functional configuration of the camera head 11102 and the CCU 11201 depicted in FIG. 25.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to the endoscope 11100 and the image pickup unit 11402 of the camera head 11102 among the above-described configurations. Specifically, the photodetection apparatus 1 of FIG. 1 can be applied to the image pickup unit 11402.

Although the endoscopic surgery system has been described here as an example, the technique according to the present disclosure may be applied to, for example, a microscopic surgery system or the like.

Note that the semiconductor apparatus of the present disclosure can also include a charge transfer section including a MOS transistor that transfers a charge from the second semiconductor region to the first semiconductor region. Specifically, in the charge transfer section 102 of FIG. 5, a MOS transistor that transfers a charge from the semiconductor region 122 to the semiconductor region 121 can be used.

Note that the effects described in the present specification are merely examples and are not limited, and other effects may be provided.

Note that the present technology can also have the following configurations.

(1)

A semiconductor apparatus comprising:
a charge transfer section configured by a MOS transistor including a first semiconductor region disposed in a semiconductor substrate, a second semiconductor region disposed in the vicinity of a surface of the semiconductor substrate, and a transfer gate disposed in a recess formed in the surface of the semiconductor substrate and having a bottom portion being a gate electrode formed in the vicinity of the first semiconductor region, and configured to transfer a charge from one of the first semiconductor region and the second semiconductor region to the other;
a separation section embedded in the surface of the semiconductor substrate and disposed adjacent to a side surface of the transfer gate; and
a notch portion formed on the side surface of the transfer gate adjacent to the separation section.
   (2)

The semiconductor apparatus according to the above (1), further comprising a channel region that is a semiconductor region formed by epitaxial growth of the recess from the surface of the semiconductor substrate, formed in a shape in contact with the transfer gate via a gate insulating film, and in which a channel is formed.

(3)

The semiconductor apparatus according to the above (2), wherein the channel region is disposed in the notch portion.

(4)

The semiconductor apparatus according to the above (2), wherein a semiconductor region of the semiconductor substrate is disposed in the notch portion.

(5)

The semiconductor apparatus according to the above (2), wherein
the channel region is formed in the semiconductor substrate other than the notch portion, and
the gate insulating film is disposed in the notch portion.
   (6)

The semiconductor apparatus according to any one of the above (2) to (5), wherein an inclined surface based on a plane orientation of the semiconductor substrate is formed at an end portion of the channel region.

(7)

The semiconductor apparatus according to any one of the above (1) to (6), further comprising a protrusion disposed at the bottom portion of the transfer gate adjacent to the notch portion.

(8)

The semiconductor apparatus according to any one of the above (1) to (7), further comprising a signal generation section that generates a signal based on the charge transferred by the charge transfer section.

(9)

The semiconductor apparatus according to any one of (1) to (8), in which
the first semiconductor region constitutes a photoelectric conversion section that performs photoelectric conversion of incident light and holds a charge generated by the photoelectric conversion,
the charge transfer section transfers a charge of the first semiconductor region to the second semiconductor region, and
the second semiconductor region holds the charge transferred by the charge transfer section.
   (10)

A photodetection apparatus including:
a photoelectric conversion section that is disposed in a semiconductor substrate and performs photoelectric conversion of incident light;
a charge holding section that is disposed in the vicinity of a surface of the semiconductor substrate and holds a charge generated by the photoelectric conversion;
a charge transfer section configured by a MOS transistor including a transfer gate disposed in a recess formed in the surface of the semiconductor substrate and having a bottom portion being a gate electrode formed in the vicinity of the photoelectric conversion section, and configured to transfer the charge of the photoelectric conversion section to the charge holding section;
a separation section embedded in the surface of the semiconductor substrate and disposed adjacent to a side surface of the transfer gate; and
a notch portion formed on the side surface of the transfer gate adjacent to the separation section.
   (11)

The photodetection apparatus according to (10), further including a channel region that is a semiconductor region formed by epitaxial growth of the recess from the surface of the semiconductor substrate, formed in a shape in contact with the transfer gate via a gate insulating film, and in which a channel is formed.

(12)

The photodetection apparatus according to (11), in which the channel region is disposed in the notch portion.

(13)

The photodetection apparatus according to (11), in which a semiconductor region of the semiconductor substrate is disposed in the notch portion.

(14)

The photodetection apparatus according to (11), in which
the channel region is formed in the semiconductor substrate other than the notch portion, and
the gate insulating film is disposed in the notch portion.
   (15)

The photodetection apparatus according to any one of (11) to (14), in which an inclined surface based on a plane orientation of the semiconductor substrate is generated at an end portion of the channel region.

(16)

The photodetection apparatus according to any one of (10) to (15), further including a protrusion disposed at a bottom portion of the transfer gate adjacent to the notch portion.

(17)

The photodetection apparatus according to any one of (10) to (16), further including a signal generation section that generates a signal based on the charge held.

### REFERENCE SIGNS LIST

1, 703 PHOTODETECTION APPARATUS
11, 21 SEMICONDUCTOR SUBSTRATE
12 PIXEL
22 PIXEL CIRCUIT
101 PHOTOELECTRIC CONVERSION SECTION
102 CHARGE TRANSFER SECTION
103 CHARGE HOLDING SECTION
129 CHANNEL REGION
131, 132, 133 SEPARATION SECTION
140 TRANSFER GATE
150 NOTCH PORTION
151 PROTRUSION
190, 191 INSULATING FILM
301 to 303 INCLINED SURFACE
403, 408 RECESS
11402, 12031, 12101 to 12105 IMAGING SECTION

What is claimed is:

1. A semiconductor apparatus, comprising:
a charge transfer section configured by a MOS transistor including a first semiconductor region disposed in a semiconductor substrate, a second semiconductor region disposed in the vicinity of a surface of the semiconductor substrate, and a transfer gate disposed in a recess formed in the surface of the semiconductor substrate and having a bottom portion being a gate electrode formed in the vicinity of the first semiconductor region, and configured to transfer a charge from one of the first semiconductor region and the second semiconductor region to the other;
a separation section embedded in the surface of the semiconductor substrate and disposed adjacent to a side surface of the transfer gate; and
a notch portion formed on the side surface of the transfer gate adjacent to the separation section.

2. The semiconductor apparatus according to claim 1, further comprising a channel region that is a semiconductor region formed by epitaxial growth of the recess from the surface of the semiconductor substrate, formed in a shape in contact with the transfer gate via a gate insulating film, and in which a channel is formed.

3. The semiconductor apparatus according to claim 2, wherein the channel region is disposed in the notch portion.

4. The semiconductor apparatus according to claim 2, wherein a semiconductor region of the semiconductor substrate is disposed in the notch portion.

5. The semiconductor apparatus according to claim 2, wherein
the channel region is formed in the semiconductor substrate other than the notch portion, and
the gate insulating film is disposed in the notch portion.

6. The semiconductor apparatus according to claim 2, wherein an inclined surface based on a plane orientation of the semiconductor substrate is formed at an end portion of the channel region.

7. The semiconductor apparatus according to claim 1, further comprising a protrusion disposed at the bottom portion of the transfer gate adjacent to the notch portion.

8. The semiconductor apparatus according to claim 1, further comprising a signal generation section that generates a signal based on the charge transferred by the charge transfer section.
